(19) United States
(12) Patent Application Publication
(10) Pub. No.: US 2025/0160151 A1
(43) Pub. Date: May 15, 2025

(54) Array Substrate, Display Panel, and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Fan He, Beijing (CN); Kemeng Tong, Beijing (CN); Cong Fan, Beijing (CN); Yujing Li, Beijing (CN); Rong Wang, Beijing (CN); Xiangdan Dong, Beijing (CN)

(21) Appl. No.: 18/834,272

(22) PCT Filed: Aug. 22, 2022
(86) PCT No.: PCT/CN2022/113926

§ 371 Date: Jul. 30, 2024

(51) Int. Cl. H10K 59/131; H10K 59/88; H10K 59/95

(52) U.S. Cl. CPC H10K 59/131; H10K 59/88; H10K 59/95

(57) ABSTRACT

An array substrate includes a substrate, data lines, fan-out leads, first dummy lines an second dummy lines. A fan-out lead includes a first lead and a second lead. The first lead extends from a lead-out region to a first wiring region. An end of the second lead is electrically connected to the first lead, and another end of the second lead is electrically connected to one data line. The first dummy lines are disposed in first wiring regions and located on a side, away from the lead-out region, of all first leads as a whole. A part of the second dummy lines is located in a second wiring region where no second lead is arranged; and another part of the second dummy lines is located in the second wiring region where the second lead is arranged and is located on at least one side of the second lead.

### CROSS-REFERENCE TO RELATED APPLICATION

This application is the United States national phase of International Patent Application No. PCT/CN2022/113926, filed Aug. 22, 2022, the disclosure of which is hereby incorporated by reference in its entirety.

### BACKGROUND OF THE INVENTION

### Field of the Invention

The present disclosure relates to the field of display technologies, and in particular, to an array substrate, a display panel, and a display apparatus.

### Description of Related Art

At present, organic light-emitting diode (OLED) display apparatuses have been widely used due to their characteristics such as self-luminescence, fast response, wide viewing angle, being capable of being fabricated on flexible substrates. The OLED display apparatus includes a plurality of sub-pixels, and each sub-pixel includes a pixel driving circuit and a light-emitting device. The pixel driving circuit drives the light-emitting device to emit light, so as to realize display.

### SUMMARY OF THE INVENTION

In an aspect, an array substrate is provided. The array substrate includes a substrate, a plurality of data lines, a plurality of fan-out leads, a plurality of first dummy lines and a plurality of second dummy lines. The substrate has a display region and a lead-out region located on a side of the display region. The display region includes first wiring regions and second wiring regions that are arranged crosswise, the first wiring regions extend in a first direction, and the second wiring regions extend in a second direction intersecting the first direction, the first direction pointing from the lead-out region to the display region. The plurality of data lines are located on the first side of the substrate and are disposed in the display region. The plurality of data lines all extend in the first direction and are sequentially arranged in the second direction. The plurality of fan-out leads are located on the first side of the substrate; a fan-out lead includes a first lead and a second lead; the first lead extends in the first direction and extends from the lead-out region to a first wiring region; the second lead extends in the second direction and is located in a second wiring region; an end of the second lead is electrically connected to the first lead, and another end of the second lead is electrically connected to one of the plurality of data lines; and the second lead and the data line are arranged in different layers. The plurality of first dummy lines are located on the first side of the substrate and extend in the first direction; the plurality of first dummy lines are disposed in the first wiring regions, and are located on a side, away from the lead-out region, of all first leads as a whole. The plurality of second dummy lines are located on the first side of the substrate and extend in the second direction; the plurality of second dummy lines are disposed in the second wiring regions; a part of the second dummy lines is located in a second wiring region where no second lead is arranged; and another part of the second dummy lines is located in the second wiring region where the second lead is arranged and is located on at least one side of the second lead in the second direction.

In some embodiments, regions between the first wiring regions and the second wiring regions are pixel unit regions, a pixel unit region of the pixel unit regions is provided therein with at least one repeating unit, and a repeating unit includes a plurality of pixel driving circuits. A pixel driving circuit includes a plurality of transistors. The array substrate further includes: a first active film layer located on the first side of the substrate; the first active film layer includes dummy active layers and pixel active layers; a pixel active layer is used to form active layers of at least some of the transistors in the pixel driving circuit, and the pixel active layer is disposed in the pixel unit region; and a dummy active layer is disposed in the first wiring region.

In some embodiments, the array substrate further includes a plurality of first power signal lines. The plurality of first power signal lines are located on the first side of the substrate and are disposed in the display region. The plurality of first power signal lines all extend in the first direction and are sequentially arranged in the second direction; and the dummy active layer is electrically connected to a first power signal line.

In some embodiments, in the first wiring region, the dummy active layer is symmetrically arranged in the second direction.

In some embodiments, in the first wiring region, the dummy active layer includes a plurality of dummy active patterns sequentially arranged in the first direction, and a dummy active pattern is disposed between two adjacent pixel unit regions in the second direction. The dummy active pattern includes two set patterns sequentially arranged in the second direction and symmetrically arranged. The pixel unit region includes a plurality of sub-pixel regions, and a sub-pixel region is provided therein with a pixel driving circuit; in the sub-pixel region, a part of the pixel active layer constitutes a preset pattern; and a set pattern and a preset pattern in a sub-pixel region adjacent to the set pattern are sequentially arranged in the second direction and are symmetrically arranged.

In some embodiments, the pixel driving circuit includes a driving transistor, a writing transistor, and a first light-emitting control transistor. In the sub-pixel region, the pixel active layer includes an active layer of the driving transistor, an active layer of the writing transistor, and an active layer of the first light-emitting control transistor; wherein a part of the active layer of the driving transistor, the active layer of the writing transistor, and the active layer of the first light-emitting control transistor together constitute a preset pattern.

In some embodiments, a size of the dummy active pattern in the first direction is greater than or equal to half of a size, in the first direction, of the pixel active layer in the pixel unit region, and is less than or equal to the size, in the first direction, of the pixel active layer in the pixel unit region.

In some embodiments, the first active film layer is disposed between the substrate and the plurality of fan-out leads.

In some embodiments, the plurality of first dummy lines are insulated from all first leads; and/or the plurality of second dummy lines are insulated from all second leads.

In some embodiments, the plurality of first dummy lines are arranged in the same layer as at least part of the first leads, and at least part of the plurality of second dummy lines are arranged in the same layer as at least part of second leads.

In some embodiments, the array substrate further includes: a plurality of first power signal lines located on the first side of the substrate and disposed in the display region; the plurality of first power signal lines all extend in the first direction and are sequentially arranged in the second direction; and the first dummy lines and the second dummy lines are electrically connected to the first power signal lines.

In some embodiments, a direction pointing from a center line of the display region in the second direction to any side of the display region in the second direction is a set direction; lengths of portions of a plurality of first leads extending to the display region decrease sequentially in the set direction; and a second lead, to which a first lead closer to the center line is electrically connected, is further away from the lead-out region.

In some embodiments, a minimum closed pattern region where all first leads located on a same side of the center line are located is a first routing region; a minimum closed pattern region where all second leads located on a same side of the center line are located is a second routing region; a part of the display region except for first routing regions and second routing regions is a third routing region; the plurality of first dummy lines are disposed in the second routing regions and the third routing region, and a part of a first dummy line located in the second routing region is insulated from any second lead; the plurality of second dummy lines are disposed in the first routing regions and the third routing region, and a part of a second dummy line located in the first routing region is insulated from any first lead.

In some embodiments, at least one first lead is a first sub-lead, and the first sub-lead is disposed on a side of the second leads away from the substrate; at least one first dummy line is a first-type dummy line, the first-type dummy line is arranged in the same layer as the first sub-lead, and the first-type dummy line is disposed in the second routing region and the third routing region.

In some embodiments, a first wiring region overlapping the first routing region is a first designated wiring region, and the first designated wiring region is provided therein with a plurality of first-type dummy lines; in the first designated wiring region, a first-type dummy line closer to the center line has a smaller length in the first direction.

In some embodiments, a number of first-type dummy lines in the first designated wiring region is the same as a number of first sub-leads in the first designated wiring region; in the first designated wiring region, the plurality of first-type dummy lines sequentially arranged in the set direction are in one-to-one correspondence with a plurality of first sub-leads sequentially arranged in the set direction; a distance between an end of a first-type dummy line close to the lead-out region and an end of a first sub-lead corresponding to the first-type dummy line away from the lead-out region is L1, where 0 μm<L1≤3 μm.

In some embodiments, a first wiring region overlapping the first routing region is a first designated wiring region, and the first designated wiring region is provided therein with a plurality of first-type dummy lines; in the first designated wiring region, lengths of the plurality of the first-type dummy lines in the first direction are equal.

In some embodiments, in the first designated wiring region, a first sub-lead with a maximum length in the first direction is a first designated lead; a distance between an end of a first-type dummy line close to the lead-out region and an end of the first designated lead away from the lead-out region is L2, where 0 μm<L2≤3 μm.

In some embodiments, a first wiring region that does not overlap the first routing region is a first set wiring region; in the first set wiring region, lengths of a plurality of first-type dummy lines are equal.

In some embodiments, second dummy lines located in the second wiring region where no second lead is arranged are first-kind dummy lines; a first-kind dummy line is electrically connected to a first power signal line through a via hole; and a first-type dummy line is electrically connected to the first-kind dummy line through a via hole.

In some embodiments, lengths of the plurality of first-kind dummy lines in the second direction are equal.

In some embodiments, a second wiring region overlapping the second routing region is a second designated wiring region; a second dummy line located on a side of the second lead away from the center line is a second-kind dummy line; in a part of the second designated wiring region on a side of the center line, a plurality of second-kind dummy lines are provided, and a number of second-kind dummy lines is equal to a number of second leads; a plurality of second-kind dummy lines sequentially arranged in the first direction are in one-to-one correspondence with a plurality of second leads sequentially arranged in the first direction; a distance between an end of a second-kind dummy line close to the center line and an end of a second lead corresponding to the second-kind dummy line away from the center line is L3, where 0 μm<L3≤3 μm.

In some embodiments, a second wiring region overlapping the second routing region is a second designated wiring region; a second dummy line located on a side of the second lead away from the center line is a second-kind dummy line; in a part of the second designated wiring region on a side of the center line, a plurality of second-kind dummy lines are provided, and lengths of the plurality of second-kind dummy lines in the second direction are equal.

In some embodiments, in the part of the second designated wiring region on the side of the center line, a second lead with a maximum length in the second direction is a second designated lead; and a distance between an end of a second-kind dummy line close to the center line and an end of the second designated lead away from the center line is L4, where 0 μm<L4≤3 μm.

In some embodiments, the second-kind dummy line is electrically connected to a first power signal line through a via hole.

In some embodiments, the array substrate further includes: at least one gate metal layer located on the first side of the substrate, a first source-drain metal layer located on a side of the at least one gate metal layer away from the substrate, and a second source-drain metal layer located on a side of the first source-drain metal layer away from the substrate. The data lines are arranged in the second source-drain metal layer, the first power signal lines are arranged in the second source-drain metal layer, the first sub-lead is arranged in the second source-drain metal layer, and the second leads are arranged in the first source-drain metal layer and/or the at least one gate metal layer.

In some embodiments, at least one first lead is a second sub-lead, and the second sub-lead and the second leads are arranged in the same layer; another part of the plurality of first dummy lines are second-type dummy lines; the second-type dummy lines and the second sub-lead is arranged in the same layer; and the second-type dummy lines are disposed in the third routing region.

In some embodiments, second dummy lines located in the first routing region are third-kind dummy lines, a third-kind dummy line is electrically connected to a first power signal line through a via hole, and any third-kind dummy line is insulated from the second sub-lead.

In some embodiments, at least one of the third-kind dummy lines includes a plurality of first sub-lines sequentially arranged in the second direction; a line-passing gap is formed between two adjacent first sub-lines in the second direction; and at least one second sub-lead passes through the line-passing gap.

In some embodiments, the array substrate further includes: at least one gate metal layer located on the first side of the substrate, a first source-drain metal layer located on a side of the at least one gate metal layer away from the substrate, and a second source-drain metal layer located on a side of the first source-drain metal layer away from the substrate. The data lines are arranged in the second source-drain metal layer, the first power signal lines are arranged in the second source-drain metal layer, the first sub-lead is arranged in the second source-drain metal layer, and the second sub-lead and the second leads are arranged in the first source-drain metal layer.

In another aspect, a display panel is provided. The display panel includes the array substrate as described in any one of the above embodiments, a light-emitting device layer, and an encapsulation layer. The light-emitting device layer is located on a side of the array substrate away from the substrate. The encapsulation layer is located on a side of the light-emitting device layer away from the array substrate.

In yet another aspect, a display apparatus is provided. The display apparatus includes: the display panel as described in any of the above embodiments, a flexible printed circuit, and a main control circuit board. The display panel includes a bonding region, and the bonding region is located on a side of the lead-out region away from the display region. An end of the flexible printed circuit is bonded to the bonding region. The main control circuit board is electrically connected to another end of the flexible printed circuit.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1A is a structural diagram of a display apparatus, in accordance with some embodiments;

FIG. 1B is a structural diagram of a display panel, in accordance with some embodiments;

FIG. 1C is a structural diagram of a display panel, in accordance with some embodiments;

FIG. 1D is a structural diagram of a display apparatus, in accordance with some embodiments;

FIG. 1E is a structural diagram of a display panel, in accordance with some embodiments;

FIG. 1F is a structural diagram of a display panel, in accordance with some embodiments;

FIG. 1G is a structural diagram of a display panel, in accordance with some embodiments;

FIG. 1H is a structural diagram of a display panel, in accordance with some embodiments;

FIG. 1I is a structural diagram of a display panel, in accordance with some embodiments;

FIG. 2A is a structural diagram of an array substrate, in accordance with some embodiments;

FIG. 2B is a structural diagram of an array substrate, in accordance with some embodiments;

FIG. 2C is a structural diagram of an array substrate, in accordance with some embodiments;

FIG. 2D is a structural diagram of an array substrate, in accordance with some embodiments;

FIG. 2E is a structural diagram of an array substrate, in accordance with some embodiments;

FIG. 3 is a structural diagram of an array substrate, in accordance with some embodiments;

FIG. 4A is a structural diagram of an array substrate, in accordance with some embodiments;

FIG. 4B is a structural diagram of an array substrate, in accordance with some embodiments;

FIG. 4C is a structural diagram of an array substrate, in accordance with some embodiments;

FIG. 4D is a structural diagram of an array substrate, in accordance with some embodiments;

FIG. 4E is a structural diagram of an array substrate, in accordance with some embodiments;

FIG. 5 is a structural diagram of an array substrate, in accordance with some embodiments;

FIG. 6 is a structural diagram of an array substrate, in accordance with some embodiments;

FIG. 7A is a structural diagram of a pixel driving circuit, in accordance with some embodiments;

FIG. 7B is a structural diagram of an array substrate, in accordance with some embodiments;

FIG. 8A is a structural diagram of an array substrate, in accordance with some embodiments;

FIG. 8B is a structural diagram of an array substrate, in accordance with some embodiments;

FIG. 8C is a structural diagram of an array substrate, in accordance with some embodiments;

FIG. 8D is a structural diagram of an array substrate, in accordance with some embodiments;

FIG. 9A is a structural diagram of an array substrate, in accordance with some embodiments;

FIG. 9B is a structural diagram of an array substrate, in accordance with some embodiments;

FIG. 10A is a structural diagram of an array substrate, in accordance with some embodiments;

FIG. 10B is a structural diagram of an array substrate, in accordance with some embodiments;

FIG. 10C is a structural diagram of an array substrate, in accordance with some embodiments;

FIG. 11A is a structural diagram of an array substrate, in accordance with some embodiments;

FIG. 11B is a structural diagram of an array substrate, in accordance with some embodiments;

FIG. 11C is a structural diagram of an array substrate, in accordance with some embodiments;

FIG. 12A is a structural diagram of an array substrate, in accordance with some embodiments;

FIG. 12B is a structural diagram of an array substrate, in accordance with some embodiments;

FIG. 12C is a structural diagram of an array substrate, in accordance with some embodiments;

FIG. 12D is a structural diagram of an array substrate, in accordance with some embodiments;

FIG. 13A is a structural diagram of an array substrate, in accordance with some embodiments;

FIG. 13B is a structural diagram of an array substrate, in accordance with some embodiments;

FIG. 13C is a structural diagram of an array substrate, in accordance with some embodiments;

FIG. 14 is a structural diagram of an array substrate, in accordance with some embodiments; and

FIG. 15 is a structural diagram of a display apparatus, in accordance with some embodiments.

### DESCRIPTION OF THE INVENTION

The technical solutions in embodiments of the present disclosure will be described clearly and completely with reference to the accompanying drawings. However, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, the terms such as “some embodiments”, “example”, or “some examples” are intended to indicate that specific features, structures, materials or characteristics related to the embodiment(s) or example(s) are included in at least one embodiment or example of the present disclosure. Schematic representations of the above term do not necessarily refer to the same embodiment(s) or example(s). In addition, specific features, structures, materials or characteristics may be included in any one or more embodiments or examples in any suitable manner.

Hereinafter, the terms “first” and “second” are only used for descriptive purposes, and are not to be construed as indicating or implying relative importance or implicitly indicating the number of indicated technical features. Thus, a feature defined with the term such as “first” or “second” may explicitly or implicitly include one or more of the features. In the description of the embodiments of the present disclosure, the term “a plurality of” or “the plurality of” means two or more unless otherwise specified.

In the description of some embodiments, the term “connected” and derivatives thereof may be used. For example, the term “connected” may be used in the description of some embodiments to indicate that two or more components are in direct physical or electrical contact with each other. The embodiments disclosed herein are not necessarily limited to the content herein.

The phrase “A and/or B” includes the following three combinations: only A, only B, and a combination of A and B.

In addition, the use of the phrase “based on” is meant to be open and inclusive, since a process, step, calculation or other action that is “based on” one or more of the stated conditions or values may, in practice, be based on additional conditions or values exceeding those stated.

The term such as “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “perpendicular” includes absolute perpendicularity and approximate perpendicularity, and an acceptable range of deviation of the approximate perpendicularity may also be, for example, a deviation within 5°. The term “equal” includes absolute equality and approximate equality, and an acceptable range of deviation of approximate equality may be, for example, that a difference between two equals is less than or equal to 5% of any one of the two equals.

It will be understood that, in a case where a layer or component is referred to as being on another layer or a substrate, it may be that the layer or component is directly on the another layer or substrate, or there may be intervening layer(s) between the layer or component and the another layer or substrate.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

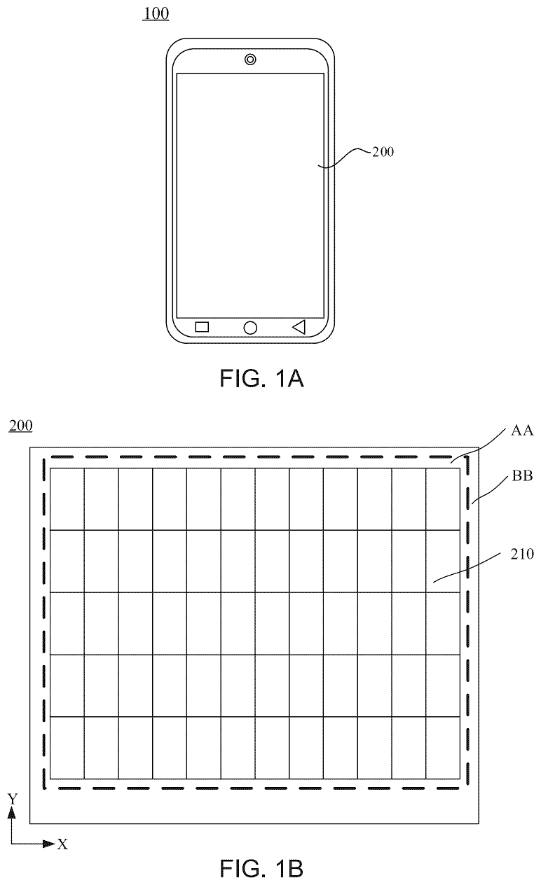

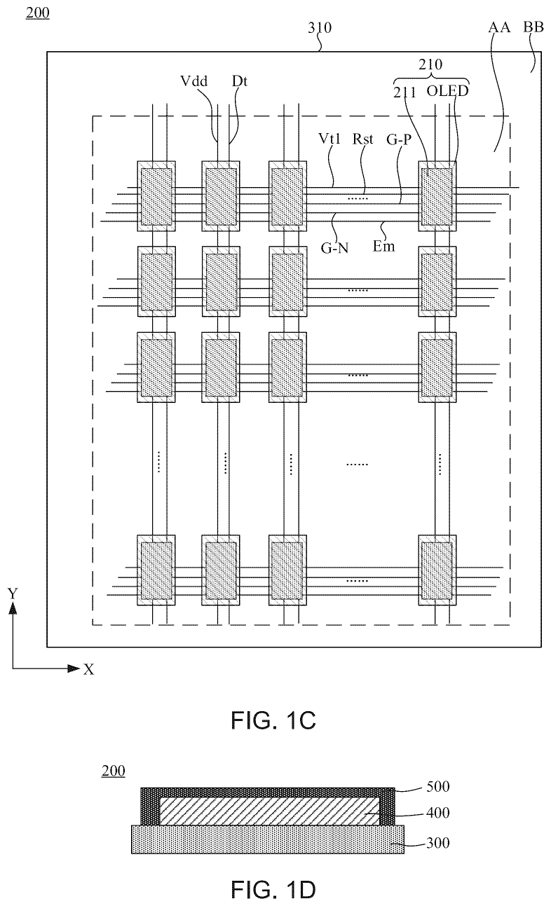

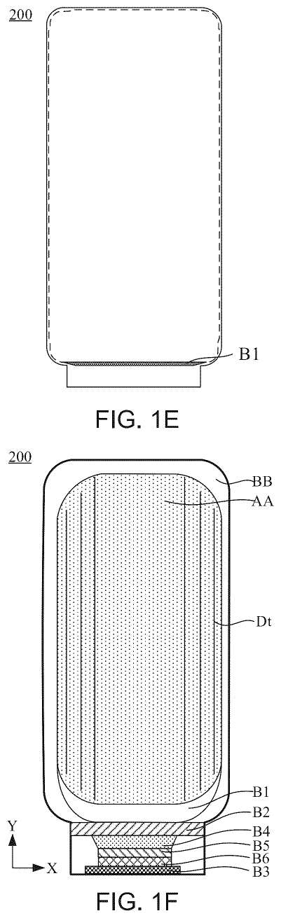

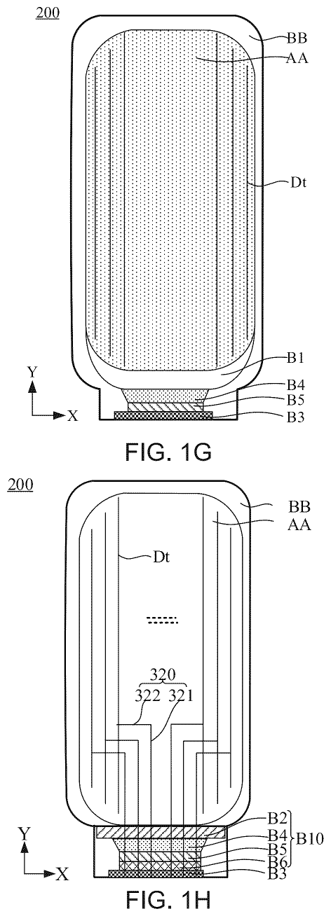

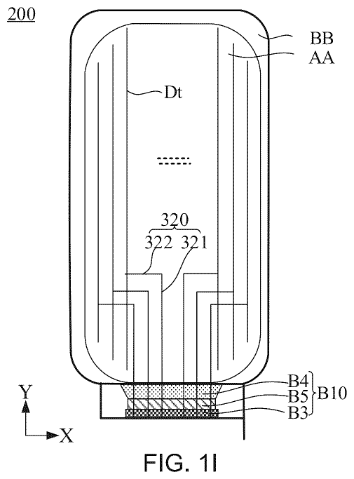

Some embodiments of the present disclosure provide a display apparatus. FIG. 1A is a diagram showing a structure of a display apparatus according to some embodiments. Referring to FIG. 1A, the display apparatus 100 is a product having a function of displaying an image (including an image in stationary or an image in motion (which may be a video)). For example, the display apparatus 100 may be any one of a display, a television, a billboard, a digital photo frame, a laser printer having a display function, a telephone, a mobile phone, a personal digital assistant (PDA), a digital camera, a portable camcorder, a view finder, a navigator, a vehicle, a large-area wall, a household appliance, an information inquiry device (e.g., a business inquiry device for a department of e-government, bank, hospital, electricity or the like) and a monitor.

The display apparatus 100 includes a display panel 200. Referring to FIG. 1B, the display panel 200 is provided with many sub-pixels 210. The sub-pixels 210 are the smallest units for the display panel 200 to display images. Each sub-pixel 210 may display a single color, such as red (R), green (G) or blue (B). The display panel 200 is provided with a large number of red sub-pixels, green sub-pixels and blue sub-pixels. The brightness (gray scales) of sub-pixels of different colors is adjusted, so that the display of various colors is realized through color combination and superposition. Thus, the display panel 200 realizes full-color display. Referring to FIG. 1C, each sub-pixel 210 includes a light-emitting device OLED and a pixel driving circuit 211 for driving the light-emitting device OLED to emit light.

Referring to FIG. 1D, the display panel 200 includes an array substrate 300, a light-emitting device layer 400 and an encapsulation layer 500 that are sequentially stacked. The array substrate 300 includes a substrate 310, and referring to FIG. 1C, the substrate 310 includes a display region AA and a peripheral region BB located at least on one side of the display region AA. For example, the peripheral region BB is arranged around the display region AA. The array substrate 300 further includes a plurality of pixel driving circuits 211 disposed on the substrate 310. The plurality of pixel driving circuits 211 may be arranged in an array on the substrate 310.

The light-emitting device layer 400 includes an anode layer, a light-emitting layer, and a cathode layer that are sequentially stacked. In some examples, an electron transport layer is disposed between the cathode layer and the light-emitting layer, and a hole transport layer is disposed between the anode layer and the light-emitting layer. The light-emitting device layer 400 is used to form a plurality of light-emitting devices OLED. The light-emitting device OLED is electrically connected to the pixel driving circuit 211, so that the pixel driving circuit 211 drives the light-emitting device OLED to emit light. The encapsulation layer 500 is capable of covering the light-emitting devices OLED, so that the light-emitting devices OLED are coated with the encapsulation layer 500. Therefore, it avoids the problem that water vapor and oxygen in an external environment enters the display panel 200, which damages organic materials in the light-emitting devices OLED, causing life shortening of the OLED display panel 200.

In addition, the array substrate 300 further includes a plurality of signal lines. For example, referring to FIG. 1C, the signal lines may include data lines Dt, first power signal lines Vdd, light-emitting control signal lines Em, first gate scan signal lines G-N, second gate scan signal lines G-P, first initialization signal lines Vt1, and reset signal lines Rst; and the plurality of signals are all electrically connected to the pixel driving circuits 211.

Referring to FIG. 1C, a plurality of data lines Dt are disposed on a first side of the substrate 310. The data lines Dt extend in a first direction Y. One data line Dt is electrically connected to a column of pixel driving circuits 211 to transmit a data signal to the pixel driving circuits 211.

In some embodiments, referring to FIGS. 1E and 1F, the peripheral region BB of the substrate 310 further includes a first fan-out region B1. Lead-out portions of the data lines Dt are arranged in the first fan-out region B1. The data lines Dt are gathered in the first fan-out region B1. The lead-out portions of the data lines Dt in the first fan-out region B1 may be defined as fan-out leads.

Referring to FIG. 1F, in some embodiments, in addition to the first fan-out region B1, the peripheral region BB of the substrate 310 further includes a bending region B2, a second fan-out region B4, a test circuit region B5, a chip region B6 and a bonding region B3. The bonding region B3, the chip region B6, the test circuit region B5, the second fan-out region B4, the bending region B2 and the first fan-out region B1 are sequentially arranged in the first direction Y and gradually close to the display region AA.

Lead-out portions of the first power signal lines Vdd are arranged in the second fan-out region B4, and the lead-out portions of the first power signal lines Vdd are gathered in the second fan-out region B4. The lead-out portions of the first power signal lines Vdd may extend to the bonding region B3.

A display screen test circuit is provided in the test circuit region B5.

A plurality of pins are provided in the chip region B6. The lead-out portions of the data lines Dt may extend to the chip region B6 by sequentially passing through the bending region B2, the second fan-out region B4 and the test circuit region B5. A plurality of pins are provided in the chip region B6. The display panel 200 may be electrically connected to a driver integrated circuit (IC) through the plurality of pins.

Among them, the bending region B2 is made of a flexible material and is capable of being bent. A part of the bending region B2, the second fan-out region B4, the test circuit region B5, the chip region B6, and the bonding region B3 need to be bent to the back of the display panel 200. In this implementation, after the part of the bending region B2, the second fan-out region B4, the test circuit region B5, the chip region B6, and the bonding region B3 are bent to the back of the display panel 200, the lead-out portions of the data lines Dt, i.e., the fan-out leads cannot be bent to the back of the display panel 200. Thus, the fan-out leads will be located in a bezel region of the display panel 200. Here, the bezel region of the display panel 200 refers to a part of the peripheral region BB which is not bent to the back of the display panel 200. Since the fan-out leads are located in the bezel region of the display panel 200, sizes of corners of the lower bezel and the size of the lower bezel will be increased.

In some other examples, the peripheral region BB does not include the bending region B2 and the chip region B6. Referring to FIG. 1G, the peripheral region BB includes the second fan-out region B4, the test circuit region B5 and the bonding region B3. In this case, first leads 321 may extend to the bonding region B3 by passing through the second fan-out region B4 and the test circuit region B5, and are electrically connected to the plurality of pins in the bonding region B3. The driver IC is bonded to a flexible printed circuit (FPC), and the FPC is bonded to the plurality of pins in the bonding region B3. That is, the driver IC is electrically connected to the plurality of pins in the bonding region B3 through the FPC. In this example, the FPC is bent to the back of the display panel 200.

In an implementation, referring to FIG. 1H, the fan-out lead 320 includes a first lead 321 extending in the first direction Y and a second lead 322 extending in a second direction X. The first direction Y and the second direction X intersect. For example, the first direction Y is perpendicular to the second direction X. The first lead 321 extends from the bending region B2 to the display region AA. The second lead 322 is electrically connected to an end of the first lead 321 located in the display region AA. An end of the second lead 322 away from the first lead 321 is electrically connected to one of the plurality of data lines Dt. Therefore, the fan-out lead 320 can transmit the data signal to the data line Dt corresponding to the fan-out lead 320. In this implementation, the fan-out leads 320 are arranged in the display region AA, so that the fan-out leads 320 are gathered in the display region AA, which is equivalent to arranging the first fan-out region in the display region AA, thereby reducing the sizes of the corners and lower bezel of the display panel 200.

In the above implementation, since the fan-out leads 320 are only located in a part of the display region AA, there is a distinct boundary line between a part of the display region AA where the fan-out leads 320 are not arranged and the part of the display region AA where the fan-out leads 320 are arranged, resulting in macroscopic visibility of the fan-out leads 320.

In view of this, some embodiments of the present disclosure provide an array substrate 300. The array substrate 300 includes: a substrate 310, and a plurality of data lines Dt, a plurality of fan-out leads 320, a plurality of first dummy lines 330, and a plurality of second dummy lines 340 that are disposed on a first side of the substrate 310.

Referring to FIG. 1H, the substrate 310 has a display region AA and a lead-out region B10 located on a side of the display region AA.

In some examples, the lead-out region B10 includes a bending region B2, a second fan-out region B4 and a test circuit region B5; and a chip region B6 and a bonding region B3 are provided on a side of the lead-out region B10 away from the display region AA.

Referring to FIG. 1I, in some other examples, the bending region B2 and the chip region B6 are not provided in the peripheral region BB. In this case, the lead-out region B10 includes the second fan-out region B4 and the test circuit region B5, and the lead-out region B10. A bonding region B3 is also provided on the side away from the display region AA.

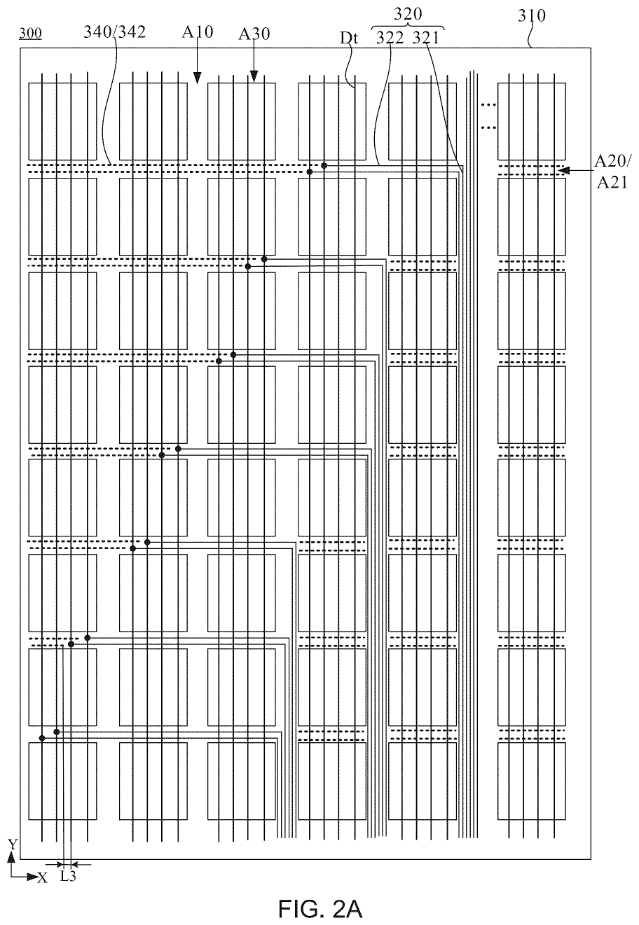

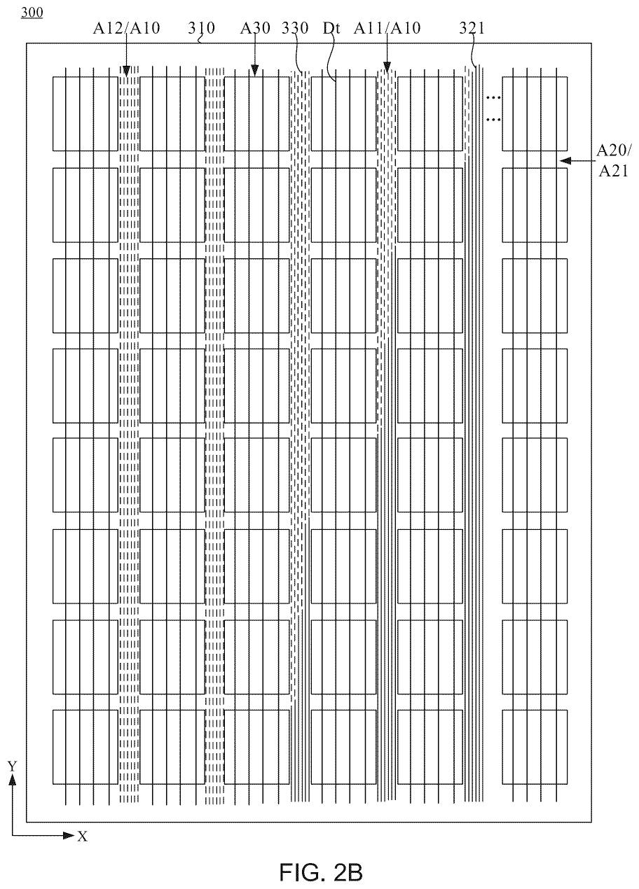

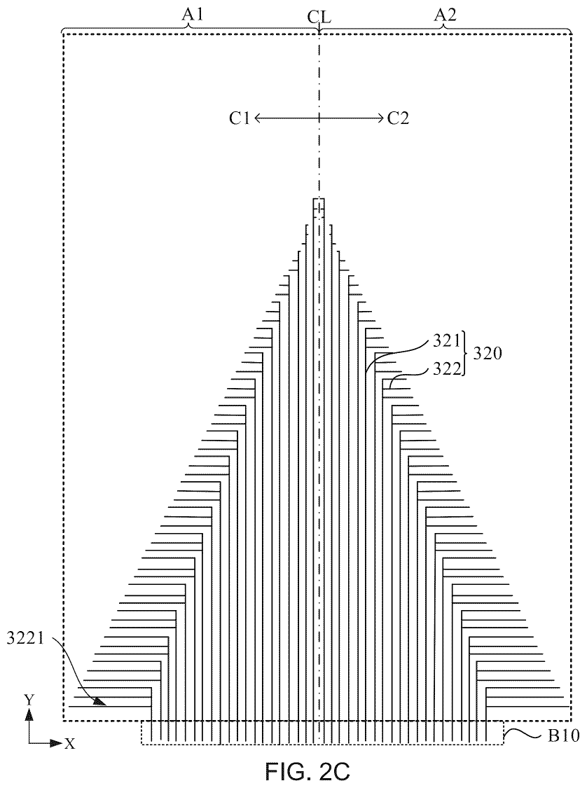

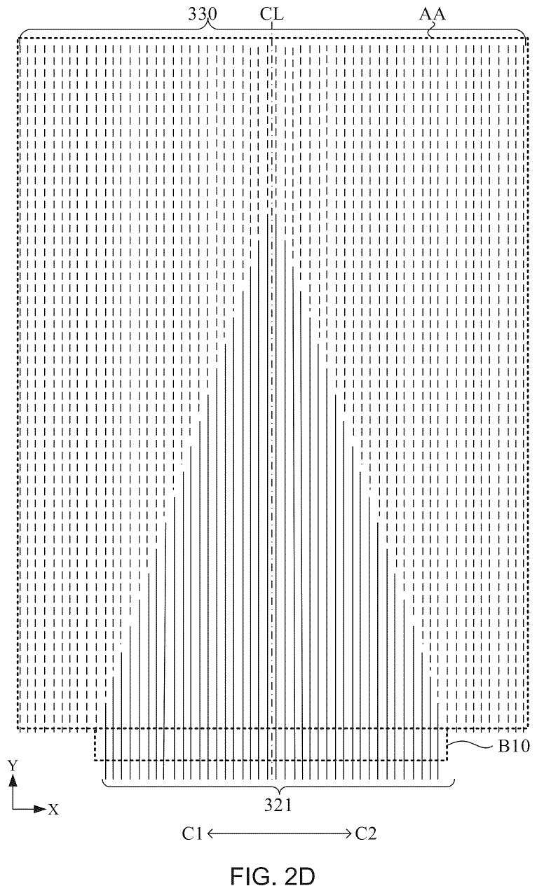

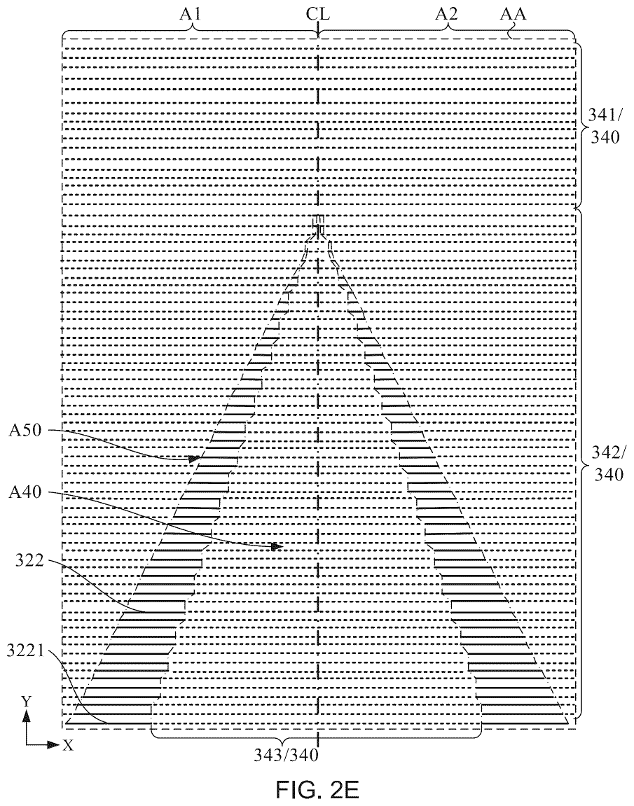

Referring to FIG. 2A, the display region AA includes first wiring regions A10 and a second wiring regions A20 that are arranged crosswise. The first wiring regions A10 extend in the first direction Y, and the second wiring regions A20 extend in the second direction X intersecting the first direction Y. The first direction Y points from the lead-out region B10 to the display region AA. For example, the first direction Y is perpendicular to the second direction X. It should be noted that the substrate shown in FIG. 2A is a part of the substrate in the array substrate.

There are a plurality of first wiring regions A10, and the plurality of first wiring regions A10 are sequentially arranged in the second direction X.

There are a plurality of second wiring regions A20, and the plurality of second wiring regions A20 are sequentially arranged in the first direction Y.

In some examples, referring to FIG. 2A, first wiring regions A10 and second wiring regions A20 that are arranged crosswise may define pixel unit regions A30. In the display panel 200, a single pixel unit region A30 may be provided therein with at least one repeat unit; a single repeat unit may include a plurality of pixel driving circuits 211; and the plurality of pixel driving circuits 211 in a single repeat unit may be used to drives light-emitting devices OLED of different colors to emit light. For example, a single repeat unit includes four pixel driving circuits 211 which are respectively used to drive one red sub-pixel, one blue sub-pixel, and two green sub-pixels to emit light.

Referring to FIG. 2A, the plurality of data lines Dt are located on the first side of the substrate 310, and are disposed in the display region AA. The plurality of data lines Dt all extend in the first direction Y, and are sequentially arranged in the second direction X.

The plurality of fan-out leads 320 are located on the first side of the substrate 310. Referring to FIG. 2A, a fan-out lead 320 includes a first lead 321 and a second lead 322. The first lead 321 extends in the first direction Y, and extends from the lead-out region B10 to the first wiring region A10. A single first wiring region A10 is provided therein with a plurality of first leads 321. In some examples, the plurality of first leads 321 are arranged in the same film layer. In some other examples, the plurality of first leads 321 are separately arranged in different film layers. For example, the plurality of first leads 321 in a single first wiring region A10 are separately arranged in different film layers.

In some examples, referring to FIG. 2B, the plurality of first wiring regions A10 of the substrate 310 include a plurality of first designated wiring regions A11 and a plurality of first set wiring regions A12; each designated wiring region A11 is provided therein with first leads 321; and any first set wiring region A12 is provided therein with no first lead 321. It should be noted that the substrate shown in FIG. 2A is a part of the substrate in the array substrate.

Referring to FIG. 2A, the second lead 322 extends in the second direction X, and is located in the second wiring region A20; an end of the second lead 322 is electrically connected to the first lead 321, and another end of the second lead 322 is electrically connected to one data line Dt of the plurality of data lines Dt. Among the plurality of second wiring regions A20, some of second wiring regions A20 are provided therein with second leads 322, and some other of second wiring regions A20 are provided therein with no second lead 322. In the second wiring region A20 where a second lead 322 is arranged, there is at least one second lead 322.

In some examples, the plurality of fan-out leads 320 are in one-to-one correspondence with and electrically connected to the plurality of data lines Dt, and a fan-out lead 320 can transmit a data signal to a data line Dt corresponding to the fan-out lead 320. The fan-out leads 320 include a plurality of first leads 321 and a plurality of second leads 322. It can be understood that, the plurality of second leads 322 are in one-to-one correspondence with and electrically connected to the plurality of data lines Dt, and the plurality of first leads 321 are in one-to-one correspondence with and electrically connected to the plurality of second leads 322. In the case where the lead-out region B10 includes the bending region B2, the second fan-out region B4 and the test circuit region B5 and the side of the lead-out region B10 away from the display region AA is further provided with the chip region B6 and the bonding region B3, first leads 321 of all the fan-out leads 320 extend to the chip region B6 through the lead-out region B10. In the case where the lead-out region B10 includes the second fan-out region B4 and the test circuit region B5 and the side of the lead-out region B10 away from the display region AA is provided with the bonding region B3, the first leads 321 of all the fan-out leads 320 extend to the bonding region B3 through the lead-out region B10.

In some other examples, the plurality of fan-out leads 320 are in one-to-one correspondence with and electrically connected to some of the plurality of data lines Dt. In the case where the lead-out region B10 includes the bending region B2, the second fan-out region B4 and the test circuit region B5 and the side of the lead-out region B10 away from the display region AA is further provided with the chip region B6 and the bonding region B3, the first leads 321 of all the fan-out leads 320 extend to the chip region B6 through the lead-out region B10, and data lines Dt that are not electrically connected to the fan-out leads 320 extend to the chip region B6 through the lead-out region B10. In the case where the lead-out region B10 includes the second fan-out region B4 and the test circuit region B5 and the side of the lead-out region B10 away from the display region AA is further provided with the bonding region B3, the first leads 321 of all the fan-out leads 320 extend to the bonding region B3 through the lead-out region B10, and the data lines Dt that are not electrically connected to the fan-out leads 320 extend to the bonding region B3 through the lead-out region B10.

In some of the following embodiments, some embodiments of the present disclosure are exemplarily described by taking an example in which the plurality of fan-out leads 320 are in one-to-one correspondence with and electrically connected to the plurality of data lines Dt. For example, the second leads 322 and the data lines Dt are arranged in different layers, so that the second lead 322 and the data line Dt, which do not correspond to each other, are insulated from each other. Each second lead 322 may be electrically connected to a data line Dt corresponding to the second lead 322 through a via hole. It should be noted that the second lead 322 and the data line Dt, which are electrically connected to each other, correspond to each other; and the second lead 322 and the data line Dt, which are insulated from each other, do not correspond to each other.

Referring to FIG. 2B, the plurality of first dummy lines 330 are located on the first side of the substrate 310 and extend in the first direction Y; and the plurality of first dummy lines 330 are disposed in the first wiring regions A10, and are located on a side, away from the lead-out region B10, of all the first leads 321 as a whole. In some examples, referring to FIG. 2B, a single first wiring region A10 is provided therein with multiple first dummy lines 330.

Referring to FIGS. 2C and 2D, FIG. 2C shows a structure of fan-out leads 320 in some embodiments. It should be noted that in FIG. 20, multiple first leads 321 located in the same first wiring region A10 are represented by the same straight line, and multiple second leads 322 located in the same second wiring region A20 are represented by the same straight line. FIG. 2D shows a structure of first dummy lines 330 corresponding to the first leads 321 in FIG. 2C. The first dummy lines 330 are located on a side, away from the lead-out region B10, of all first leads 321 as a whole. The side, away from the lead-out region B10, of the first leads 321 as a whole includes portions of the first wiring regions A10 where the first leads 321 are arranged, and first wiring regions A10 where no first lead 321 is arranged.

Referring to FIG. 2A, the plurality of second dummy lines 340 are located on the first side of the substrate 310 and extend in the second direction X. The plurality of second dummy lines 340 are disposed in the second wiring regions A20.

Referring to FIG. 2E, a part of the second dummy lines 340 is located in a second wiring region A20 where no second lead 322 is arranged; and another part of the second dummy lines 340 is located in a second wiring region A20 where the second lead 322 is arranged, and is located on at least one side of the second lead 322 in the second direction X.

For example, referring to FIG. 2E, a second lead electrically connected to a data line Dt located at an edge is a second lead 3221. In the second wiring region A20 where the second lead 3221 is located, the second dummy line 340 is only located on a side of the second lead 3221 away from the data line Dt to which the second lead 3321 is electrically connected. In the second wiring regions A20 where other second leads 322 are located, both sides of multiple second leads 322 in the second direction X are each provided with second dummy lines 340.

In the array substrate 300 provided in some of the above embodiments of the present disclosure, since the first dummy lines 330 are provided in the first wiring regions A10, there is no significant difference between some of the first wiring regions A10 where the first leads 321 are provided and some other of the first wiring regions A10 where no first lead 321 is provided; since the second dummy lines 340 are provided in the second wiring regions A20, there is no significant difference between some of the second wiring regions A20 where the second leads 322 are provided and some other of the second wiring regions A20 where no second lead 322 is provided. Therefore, there is no significant difference between regions where the fan-out leads 320 are arranged and regions where no fan-out lead 320 is arranged, and the macroscopic visibility of the fan-out leads 320 is reduced.

In some embodiments, all first dummy lines 330 are insulated from all first leads 321. That is, any first dummy line 330 is insulated from the first lead 321. In some examples, a gap may be formed between the first dummy line 330 and the first lead 321, thereby insulating the first dummy line 330 from the first lead 321. The first dummy lines 330 may overlap with other structures in the display panel 200, causing interference to the first dummy lines 330. However, the first dummy lines 330 are insulated from the first leads 321, so that data signals in the first leads 321 will not be disturbed.

In some embodiments, the plurality of second dummy lines 340 are insulated from all second leads 322. In some examples, a gap may be formed between the second dummy line 340 and the second lead 322, so that the second dummy line 340 is insulated from the second lead 322. The second dummy lines 340 may overlap with other structures in the display panel 200, causing interference to the second dummy lines 340. However, the second dummy lines 340 are insulated from the second leads 322, so that data signals in the second leads 322 will not be disturbed.

In some embodiments, the plurality of first dummy lines 330 are arranged in the same layer as at least a part of the first leads 321.

In some examples, all first leads 321 may be arranged in the same film layer. Correspondingly, all first dummy lines 330 may be arranged in the same film layer as all first leads 321.

In some other examples, the plurality of first leads 321 may be arranged in two film layers. In this case, the first dummy lines 330 may be arranged in any one of the film layers where the first leads 321 are located.

In still some other examples, the plurality of first leads 321 may be arranged in two film layers. In this case, the first dummy lines 330 may be arranged in both film layers where the first leads 321 are located.

In some of the above embodiments, since the first dummy lines 330 are arranged in the same layer as at least part of the first leads 321, the light effect of the first dummy lines 330 and the light effect of the first leads 321 are substantially or exactly the same. As a result, the macroscopic visibility of the regions where the fan-out leads 320 are located is further reduced.

In some embodiments, at least part of the plurality of second dummy lines 340 is arranged in the same layer as at least part of the second leads 322. In some examples, a part of the plurality of second dummy lines 340 may be arranged in the same layer as a part of the plurality of second leads 322. In this case, the plurality of second leads 322 may be arranged in two film layers. A part of the plurality of second dummy lines 340 is arranged in the same layer as a part of the second leads 322, and another part of the plurality of second dummy lines 340 is arranged in the same layer as another part of the second leads 322.

In some other examples, some of the plurality of second dummy lines 340 may be arranged in the same layer as all the second leads 322.

In still some other examples, all the second dummy lines 340 may be arranged in the same layer as all the second leads 322. In this case, all the second leads 322 can be arranged in the same layer, and all the second dummy lines 340 can be arranged in the same layer.

In still some other examples, all the second dummy lines 340 may be arranged in the same layer as part of the plurality of second leads 322. In this case, the second leads 322 may be arranged in two film layers, and the second dummy lines 340 are arranged in the same layer as second leads 322 in one of the film layers. For example, the second dummy lines 340 are arranged in the same layer as second leads 322 which are farther away from the substrate 310.

Since the second dummy lines 340 and the second leads 322 are arranged in the same layer, the second dummy lines 340 and the second leads 322 cause the same light effect. As a result, the macroscopic visibility of the fan-out leads 320 can be further reduced.

In some embodiments, the array substrate 300 further includes a plurality of first power signal lines Vdd (e.g., the first power signal lines Vdd shown in FIG. 1C). The plurality of first power signal lines Vdd are located on the first side of the substrate 310, and are disposed in display region AA. The plurality of first power signal lines Vdd all extend in the first direction Y, and are arranged sequentially in the second direction X. The first dummy lines 330 and the second dummy lines 340 are electrically connected to the first power signal lines Vdd.

The first power signal line Vdd may transmit a power signal to a column of pixel driving circuits 211. The first power signal line Vdd is electrically connected to anodes of light-emitting devices OLED, and cathodes of the light-emitting devices OLED are electrically connected to second power signal line(s) Vss. For example, a voltage of a first power signal transmitted by the first power signal line Vdd is higher than a voltage of a second power signal transmitted by the second power signal line Vss. The first dummy lines 330 and the second dummy lines 340 are electrically connected to the first power signal lines Vdd, so as to avoid the electrostatic accumulation caused by the floating of the first dummy lines 330 and the second dummy lines 340. In addition, after the first power signal lines Vdd are electrically connected to the first dummy lines 330 and the second dummy lines 340, loads of the first power signal lines Vdd may be reduced, so that the brightness uniformity of the display panel 200 is improved.

Since the first dummy lines 330 are insulated from the first leads 321 and the second dummy lines 340 are insulated from the second leads 322, the first power signal lines Vdd are not electrically connected to the first leads 321 and the second leads 322. Therefore, the data signals in the first leads 321 and the second leads 322 will not be disturbed.

In some embodiments, referring to FIG. 2C, a direction from a center line CL of the display region AA in the second direction X to any side of the display region AA in the second direction X is a set direction. The center line CL divides the display region AA into two display sub-regions. For example, the two display sub-regions are a first display sub-region A1 and a second display sub-region A2. In the first display sub-region A1, a direction pointed by an arrow C1 is the set direction. In the second display sub-region A2, a direction pointed by an arrow C2 is the set direction.

Lengths of portions of the plurality of first leads 321 extending to the display region AA sequentially decrease in the set direction. For example, referring to FIGS. 2C and 2D, in the first display sub-region A1, lengths, in the first direction Y, of portions of the first leads 321 located in the display region AA sequentially decrease in the set direction C1. In the second display sub-region A2, lengths, in the first direction Y, of portions of the first leads 321 located in the display region AA sequentially decrease in the set direction C2.

Referring to FIG. 2C, a second lead 322, to which a first lead 321 closer to the center line CL is connected, is further away from the lead-out region B10. A second lead 322, to which a first lead 321 closest to the center line CL is electrically connected, is farthest from the lead-out region B10. A direction from an end of the second lead 322 connected to the first lead 321 to another end of the second lead 322 connected to the data line Dt is an extending direction of the second lead 322. Extending directions of second leads 322 on both sides of the center line CL are opposite. That is, the extending direction of each second lead 322 is the same as the set direction of the display sub-region where the second lead 322 is located.

Referring to FIG. 2C, a data line Dt (not shown in FIG. 2C), to which a second lead 322 closer to the lead-out region B10 is electrically connected, is further away from the center line CL. For the second lead 322 that is closer to the lead-out region B10, a distance between an end of the second lead 322 away from the center line CL and the center line CL is greater. Therefore, in the first direction Y, distances of ends of the plurality of second leads 322 away from the center line CL from the center line CL gradually decrease. In this way, the wiring of the fan-out leads 320 may be short, thereby saving costs.

In some other embodiments, the data line Dt, to which the second lead 322 closer to the lead-out region B10 is electrically connected, is closer to the center line CL.

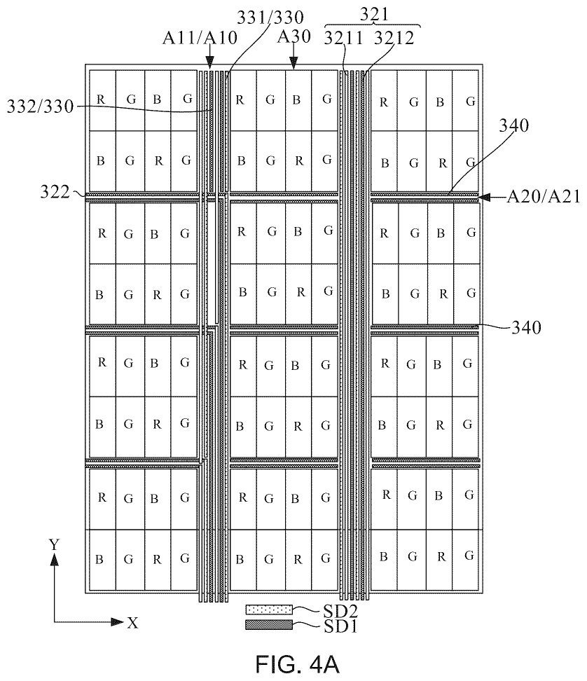

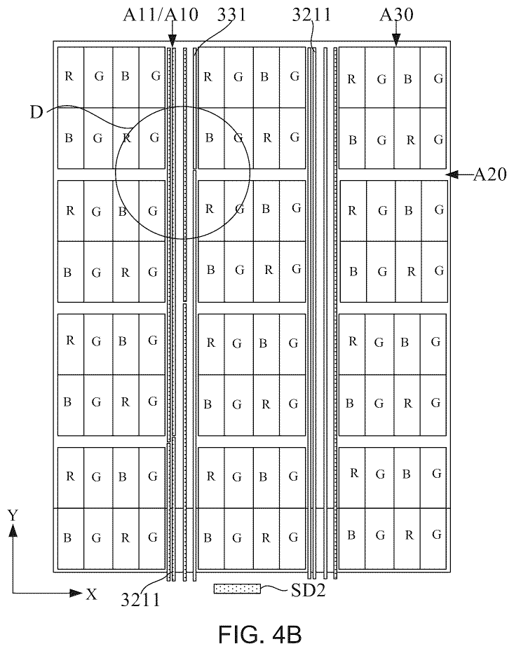

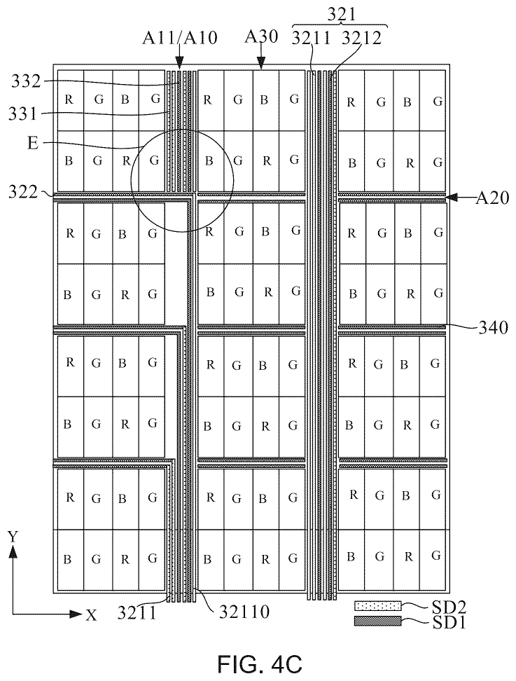

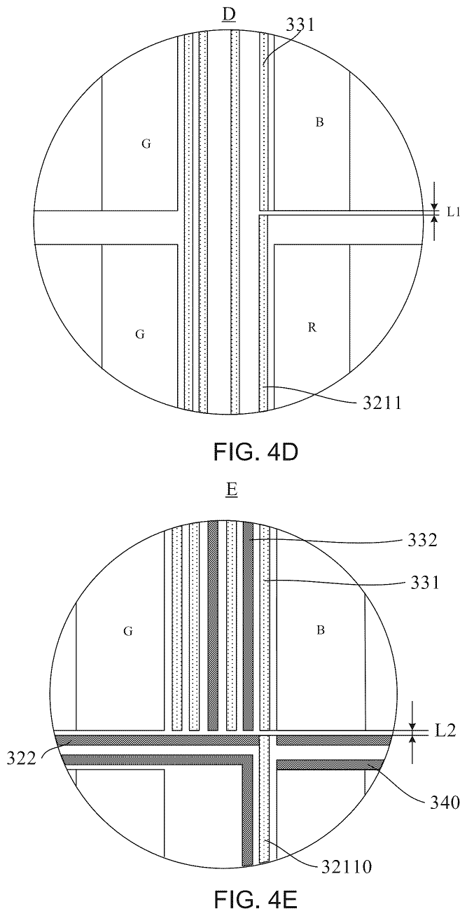

In some examples, referring to FIG. 4A, the plurality of first wiring regions A10 and the plurality of second wiring regions A20 surround a plurality of pixel unit regions A30; each pixel unit region A30 includes a plurality of sub-pixel regions; and a plurality of sub-pixel regions on the substrate 310 are arranged in multiple rows and multiple columns. A plurality of sub-pixel regions in a row of sub-pixel regions are sequentially arranged in the second direction X. A plurality of sub-pixel regions in a column of sub-pixel regions are sequentially arranged in the first direction Y.

In some examples, the substrate 310 is provided with M columns of sub-pixel regions and N rows of sub-pixel regions. Correspondingly, the array substrate 300 is provided with M data lines Dt. Therefore, the array substrate 300 may be provided with M fan-out leads 320. That is, the array substrate 300 includes M second leads 322 and M first leads 321. In some examples, a row of pixel unit regions A30 includes two rows of sub-pixel regions. In this case, M/2 rows of pixel unit regions A30 are provided on the substrate 310. A column of pixel unit regions A30 includes four columns of sub-pixel regions. In this case, N/4 columns of pixel unit regions A30 are provided on the substrate 310.

In some examples, a size of the display region AA in the first direction Y is greater than a size of the display region AA in the second direction X; and in the display region AA, the number of rows of sub-pixel regions is greater than the number of columns of sub-pixel regions. That is, N is greater than M.

In some examples, referring to FIG. 2A, a second wiring region A20 in which second lead(s) 322 are provided is a second designated wiring region A21. The second designated wiring region A21 is provided therein with at least one second lead 322 on each of both sides of the center line CL. For example, on one side of the center line CL, a single second designated wiring region A21 is provided therein with two second leads 322. Therefore, a single second designated wiring region A21 is provided therein with four second leads 322. In addition, since a row of pixel unit regions A30 includes two rows of sub-pixel regions, the first lead 321 with the maximum size in the first direction Y passes through at least M/2 rows of sub-pixel regions. Since N is greater than M, M/2 is less than N/2. Thus, the number of sub-pixel regions that the first lead 321 with the maximum size in the first direction Y passes through may be less than or equal to N/2, and the length of any first lead 321 in the display region AA may be not greater than a half of the size of the display region AA in the first direction Y.

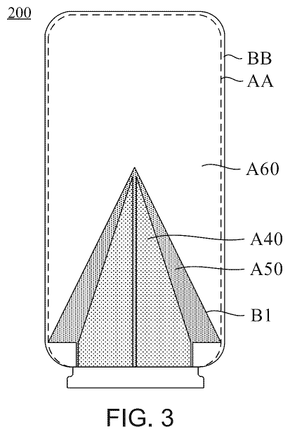

In some embodiments, referring to FIG. 3, a minimum closed pattern region where all first leads 321 on the same side of the center line CL are located is a first routing region A40; a minimum closed pattern region where all second leads 322 on the same side of the center line CL are located is a second routing region A50; and a part of the display region AA other than first routing regions A40 and second routing regions A50 is a third routing region A60.

In some embodiments, two first routing regions A40 located on both sides of the center line CL are arranged symmetrically with the center line CL as a symmetry line. Two second routing regions A50 located on both sides of the center line CL are arranged symmetrically with the center line CL as a symmetry line. Therefore, the routing of the fan-out leads 320 is regular, which facilitates the processing and improves the convenience of production and processing.

The first leads 321 are arranged in the first routing regions A40. The first dummy lines 330 are arranged in the second routing region A50 and the third routing region A60. A portion of the first dummy line 330 located in the second routing region A50 is insulated from any second lead 322. In some examples, the second leads 322 and the first dummy lines 330 are arranged in different layers, so that the portion of the first dummy line 330 located in the second routing region A50 is insulated from the second lead 322.

The second lead 322 is arranged in the second routing region A50. The second dummy line 340 is arranged in the first routing region A40 and the third routing region A60. A portion of the second dummy line 340 located in the first routing region A40 is insulated from any first lead 321. In some examples, the second dummy lines 340 and the first leads 321 are arranged in different layers, so that the portion of the second dummy line 340 located in the first routing region A40 is insulated from the first lead 321.

In some embodiments, referring to FIG. 4A, at least one first lead 321 is a first sub-lead 3211, and the first sub-lead 3211 is disposed on a side of the second lead 322 away from the substrate 310. At least one first dummy line 330 is a first-type dummy line 331. The first-type dummy line 331 and the first sub-lead 3211 are arranged in the same layer. The first-type dummy line 331 is arranged in the second routing region A50 and the third routing region A60.

Referring to FIG. 4A, a first wiring region A10 in which the first leads 321 are provided is a first designated wiring region A11. In some examples, a single first designated wiring region A11 is provided therein with at least one first sub-lead 3211. Correspondingly, a single first designated wiring region A11 is provided therein with at least one first-type dummy line 331.

In some examples, all the first leads 321 are first sub-leads 3211; and correspondingly, all the first dummy lines 330 are first-type dummy lines 331.

In some other examples, the plurality of first leads 321 include first sub-leads 3211 and second sub-leads 3212 that are arranged in different film layers; a film layer where the first sub-leads 3211 are located is located on a side, away from the substrate 310, of a film layer where the second sub-leads 3212 are located. In this case, the first-type dummy lines 331 may only be arranged in the film layer where the first sub-leads 3211 are located. Since the first sub-leads 3211 are closer to a light-emitting surface of the display panel 200, the first sub-leads 3211 are more macroscopically visible. The first-type dummy lines 331 are only arranged in the film layer where the first sub-leads 3211 are located, which reduces the macroscopic visibility of the fan-out leads 320 and saves costs.

In some other embodiments, the first-type dummy lines 331 may be arranged in the film layer where the first sub-leads 3211 are located, and second-type dummy lines 332 may be arranged in the film layer where the second sub-leads 3212 are located, so as to further reduce the macroscopic visibility of the fan-out leads 320.

In some embodiments, referring to FIG. 2B, a single first designated wiring region A11 is provided therein with a plurality of first-type dummy lines 331 and a plurality of first sub-leads 3211. In a single first designated wiring region A11, portions of the plurality of first sub-leads 3211 extend to the display region AA have different lengths in the first direction Y. In a single first designated wiring region A11, the plurality of first-type dummy lines 331 have different lengths in the first direction Y.

In some embodiments, referring to FIGS. 4A and 4B, the number of first-type dummy lines 331 in a single first designated wiring region A11 is the same as the number of first sub-leads 3211 in a single first designated wiring region A11. In the first designated wiring region A11, the plurality of first-type dummy lines 331 sequentially arranged in the set direction are in one-to-one correspondence with the plurality of first sub-leads 3211 sequentially arranged in the set direction. Referring to FIG. 4D, FIG. 4D is a partially enlarged view of the region D in FIG. 4B. A distance between an end of a first-type dummy line 331 close to the lead-out region B10 and an end, away from the lead-out region B10, of a first sub-lead 3211 corresponding to the first-type dummy line 331 is L1, where 0 μm<L1≤3 μm. A gap exists between the first-type dummy line 331 and the first sub-lead 3211, so that the first-type dummy line 331 is insulated from the first sub-lead 3211. The smaller the value range of L1, the less likely it is to view the gap between the first-type dummy line 331 and the first sub-lead 3211. L1 has a smaller value range, so that the gap between the first-type dummy line 331 and the first sub-lead 3211 is less likely to be viewed.

In some of the above embodiments, the lengths of the portions of the first leads 321 extending to the display region AA gradually decrease in the set direction. Based on this, in some embodiments, referring to FIGS. 4A and 4B, a single first designated wiring region A11 is provided therein with a plurality of first-type dummy lines 331. In the first designated wiring region A11, the first-type dummy line 331 closer to the center line CL has a smaller length in the first direction Y. It can be seen from the above, the region where the first leads 321 are located is the first routing region A40, and the first wiring region A10 overlapping the first routing region A40 is the first designated wiring region A11.

In some of the above embodiments, the sizes, in the first direction Y, of the plurality of first-type dummy lines 331 in the first designated wiring region A11 gradually decrease, so that the layout of the plurality of first-type dummy lines 331 is regular, which is convenient for production.

The above description introduces an arrangement rule for the plurality of first-type dummy lines 331 in the first designated wiring region A11. Another arrangement rule for the plurality of first-type dummy lines 331 in the first designated wiring region A11 will be introduced below.

In some embodiments, referring to FIG. 4C, in a single first designated wiring region A11, the lengths of the plurality of first-type dummy lines 331 in the first direction Y are equal, which facilitates the fabrication of the first-type dummy lines 331.

In some embodiments, referring to FIG. 4C, in a single first designated wiring region A11, the first sub-lead 3211 with the maximum length in the first direction Y is a first designated lead 32110. Referring to FIG. 4E, FIG. 4E is a partially enlarged view of the region E in FIG. 4C. A distance between an end of the first-type dummy line 331 close to the lead-out region B10 and an end of the first designated lead 32110 away from the lead-out region B10 is L2, where 0 μm<L2≤3 μm.

In some of the above embodiments, lengths of portions of the first leads 321 extending to the display region AA gradually decreases in the set direction. Based on this, in a single first designated wiring region A11, a distance between the first designated lead 32110 and the center line CL is less than a distance between another first sub-lead 3211 and the center line CL. In a single first designated wiring region A11, a distance between any first sub-lead 3211 except for the first designated lead 32110 and the first-type dummy line 331 is greater than L2.

In some embodiments, referring to FIG. 2B, a first wiring region A10 that does not overlap the first routing region A40 is a first set wiring region A12. In the first set wiring region A12, lengths of a plurality of first-type dummy lines 331 in the first direction Y are equal.

No first lead 321 is arranged in the first set wiring region A12. The number of first-type dummy lines 331 in the first set wiring region A12 is the same as the number of first-type dummy lines 331 in the first designated wiring region A11.

The arrangement rules for the first-type dummy lines 331 are introduced above. An arrangement rule for the second dummy line 340 will be introduced below.

In some embodiments, referring to FIG. 2E, a second dummy line 340 located in the second wiring region A20 where no second lead 322 is arranged is a first-kind dummy line 341, and lengths of a plurality of first-kind dummy lines 341 in the second direction X are equal. The plurality of first-kind dummy lines 341 are located on a side of all the second leads 322 away from the lead-out region B10.

In some embodiments, the first-kind dummy line 341 is electrically connected to the first power signal line Vdd through a via hole, and the first-type dummy line 331 is electrically connected to the first-kind dummy line 341 through a via hole.

The second dummy line 340 intersects the first power signal line Vdd, and they are located in different film layers. Any second dummy line 340 (including the first-kind dummy line 341) may pass through multiple first power signal lines Vdd. Therefore, the second dummy line 340 and the first power signal line Vdd may be connected through a via hole, causing the second dummy line 340 to receive the power signal. The first-kind dummy line 341 and the first-type dummy line 331 intersect and are located in different layers. The first-kind dummy line 341 is located in the third routing region A60, and the first-type dummy line 331 is located in the third wiring region A60 and the second routing region A50. Therefore, a portion of the first-type dummy line 331 located in the third routing region A60 may be connected to the first-kind dummy line 341 through a via hole, causing the first-type dummy line 331 to be electrically connected to the first power signal line Vdd.

In some embodiments, referring to FIGS. 2A and 4A, a second wiring region A20 overlapping the second routing region A50 is a second designated wiring region A21.

Referring to FIGS. 2A and 2E, a second dummy line 340 located on a side of the second lead 322 away from the center line CL is a second-kind dummy line 342. In the first display sub-region A1 or the second display sub-region A2, the second-kind dummy line 342 is located on a side of the second lead 322 away from the center line CL, that is, on a side of the second routing region A50 away from the center line CL.

In a part of a single second designated wiring region A21 on a side of the center line CL, a plurality of second-kind dummy lines 342 are arranged, and the number of second-kind dummy lines 342 is the same as the number of second leads 322. A single second designated wiring region A21 is divided into two parts by the center line CL, one part is located in the first display sub-region A1, and another part is located in the second display sub-region A2. In a part of the second designated wiring region A21 located in the first display sub-region A1 or a part of the second designated wiring region A21 located in the second display sub-region A2, the number of second-kind dummy lines 342 is the same as the number of second leads 322.

Referring to FIG. 2A, a plurality of second-kind dummy lines 342 arranged sequentially in the first direction Y are in one-to-one correspondence with a plurality of second leads 322 sequentially arranged in the first direction Y; a distance between an end of a second-kind dummy line 342 close to the center line CL and an end, away from the center line CL, of a second lead 322 corresponding to the second-kind dummy line 342 is L3, where 0 μm<L3≤3 μm. A gap exists between the second-kind dummy line 342 and the second lead 322, so that the second-kind dummy line 342 is insulated from the second lead 322. The smaller the value range of L3, the less likely it is to view the gap between the second-kind dummy line 342 and the second lead 322. L3 has a small value range, so that the gap between the second-kind dummy line 342 and the second lead 322 is less likely to be viewed.

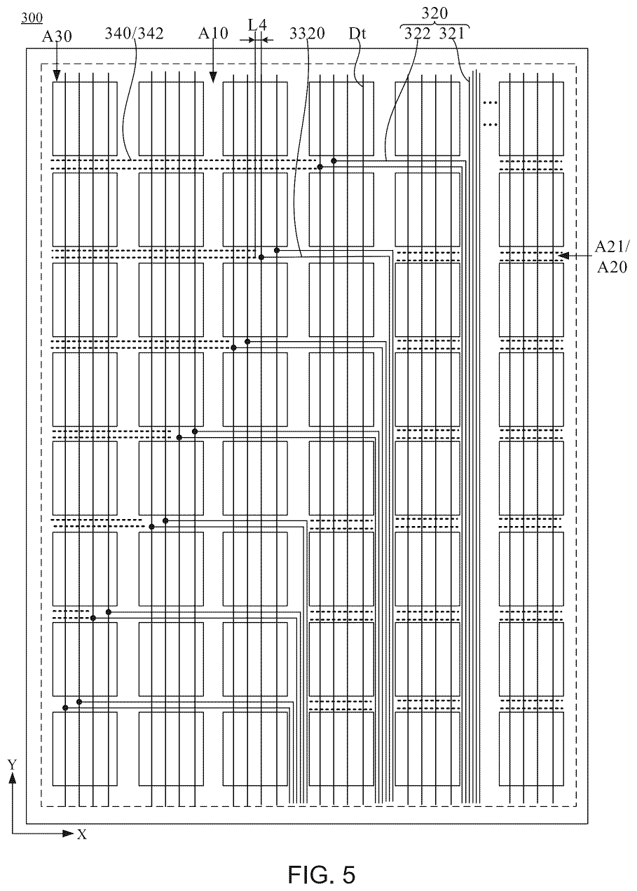

In some of the above embodiments, in a single second designated wiring region A21, the sizes of the plurality of second-kind dummy lines 342 in the second direction X are different. In some other embodiments, referring to FIG. 5, in a part of a single second designated wiring region A21 on a side of the center line CL, a plurality of second-kind dummy lines 342 are arranged, and lengths of the plurality of second-kind dummy lines 342 in the second direction X are equal, which facilitates the fabrication of the second-kind dummy lines 342.

Based on an embodiment in which the sizes, in the second direction X, of the plurality of second-kind dummy lines 342 in a single second designated wiring region A21 are equal, referring to FIG. 5, in a part of a single second designated wiring region A21 on a side of the center line CL, a second lead 322 with the maximum length in the second direction X is a second designated lead 3320; a distance between an end of the second-kind dummy line 342 close to the center line CL and an end of the second designated lead 3320 away from the center line CL is L4, where 0 μm<L4≤3 μm. The smaller the value range of L4, the less likely it is to view the gap between the second-kind dummy line 342 and the second lead 322. L4 has a small value range, so that the gap between the second-kind dummy line 342 and the second lead 322 is less likely to be viewed.

Referring to FIG. 5, in a part of a single second designated wiring region A21 located on a side of the center line CL, a distance between an end of the second designated lead 3320 away from the center line CL and the center line CL is greater than a distance between an end of another second lead 332 away from the center line CL and the center line CL.

In a single second designated wiring region A21, a distance between any second lead 322 except for the second designated lead 3320 and the second-kind dummy line 342 is greater than L4.

In some embodiments, the second-kind dummy line 342 is electrically connected to the first power signal line Vdd through a via hole. Each second-kind dummy line 342 may pass through multiple first power signal lines Vdd.

The above description introduces some wiring rules for the fan-out leads 320, the first dummy lines 330 and the second dummy lines 340 in the array substrate 300. The film layers where the fan-out leads 320 and other signal lines are located will be introduced below.

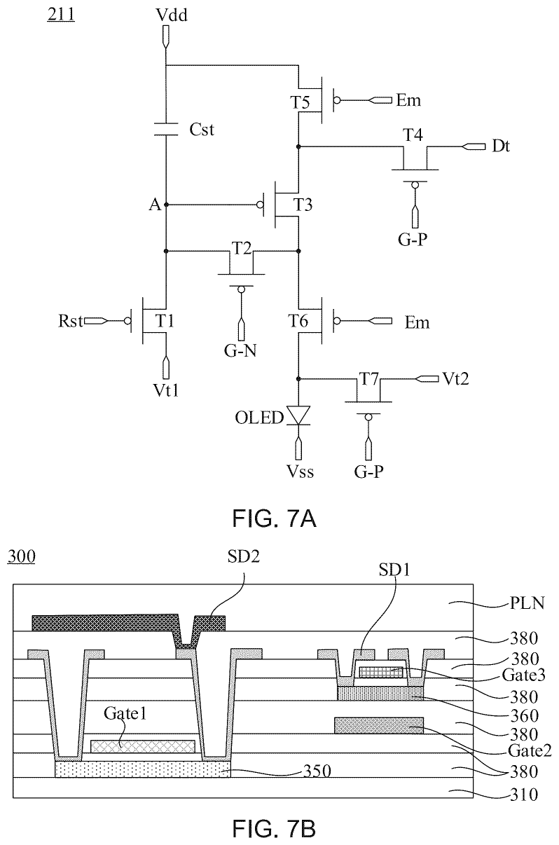

In some embodiments, referring to FIG. 7B, the array substrate 300 further includes: at least one gate metal layer located on the first side of the substrate 310, a first source-drain metal layer SD1 located on a side of the at least one gate metal layer away from the substrate 310, and a second source-drain metal layer SD2 located on a side of the first source-drain metal layer SD1 away from the substrate 310. In some examples, the array substrate 300 includes one gate metal layer. In some other examples, the array substrate 300 includes two gate metal layers. In still some other examples, the array substrate 300 includes three gate metal layers.

The data lines Dt are arranged in the second source-drain metal layer SD2, and the first power signal lines Vdd are arranged in the second source-drain metal layer SD2.

In some of the above embodiments, the first leads 321 only include the first sub-leads 3211. Based on this, the first sub-leads 3211 are arranged in the second source-drain metal layer SD2, and the second leads 322 are arranged in the first source-drain metal layer SD1 and/or the at least one gate metal layer. In a case where the array substrate 300 includes a plurality of gate metal layers, the second leads 322 may be arranged in any gate metal layer.

Referring to FIGS. 4A and 4C, in addition to the first sub-leads 3211, the first leads 321 further include the second sub-leads 3212. In some embodiments, at least one first lead 321 is a second sub-lead 3212, and the second sub-lead 3212 and the second leads 322 are arranged in the same layer. Another part of the plurality of first dummy lines 330 is second-type dummy lines 332. The second-type dummy lines 332 and the second sub-leads 3212 are arranged in the same layer. The second-type dummy lines 332 are arranged in the third routing region A60.

In a case where all the second leads 322 are arranged in the first source-drain metal layer SD1 and the at least one gate metal layer, the first source-drain metal layer SD1 is located on a side of all gate metal layer(s) away from the substrate 310. In this case, all second dummy lines 340 may be arranged in the first source-drain metal layer SD1. Of course, in other examples, part of the second dummy lines 340 may be arranged in the first source-drain metal layer SD1, and the remaining part of the second dummy lines 340 may be arranged in the gate metal layer(s) where some of the second leads 322 are located.

In a case where all the second leads 322 are arranged in the first source-drain metal layer SD1, all the second dummy lines 340 may be arranged in the first source-drain metal layer SD1.

In a case where all the second leads 322 are arranged in the at least one gate metal layer, all the second dummy lines 340 may be arranged in the at least one gate metal layer. If all the second leads 322 are arranged in one gate metal layer, then all the second dummy lines 340 are arranged in the one gate metal layer. If all the second leads 322 are arranged in multiple (such as two or three) gate metal layers, the plurality of second dummy lines 340 may be arranged in the multiple gate metal layers, or the plurality of second dummy lines 340 may be arranged in a gate metal layer farthest from the substrate 310 among the multiple gate metal layers.

The second leads 322 are arranged in the second routing regions A50, and the second-type dummy lines 332 are arranged in the third routing region A60. Therefore, the second-type dummy lines 332 do not overlap the second leads 322. As a result, the second-type dummy lines 332 are insulated from the second leads 322.

In some embodiments, referring to FIG. 2E, second dummy lines 340 located in the first routing region A40 are third-kind dummy lines 343. The third-kind dummy line 343 is electrically connected to the first power signal line Vdd through a via hole. Any third-kind dummy line 343 is insulated from the second sub-leads 3212.

In some examples, each third-kind dummy line 343 may pass through multiple first power signal lines Vdd, and each third-kind dummy line 343 may be electrically connected to at least one first power signal line Vdd. For example, a single third-kind dummy line 343 may be electrically connected to a single first power signal line Vdd; or a single third-kind dummy line 343 may be electrically connected to multiple first power signal lines Vdd.

In some examples, the second sub-leads 3212 are located in the first routing regions A40, and the third-kind dummy lines 343 are also disposed in the first routing regions A40. Since the second sub-leads 3212 and the third-kind dummy lines 343 are located in different layers, the second sub-leads 3212 are insulated from the third-kind dummy lines 343.

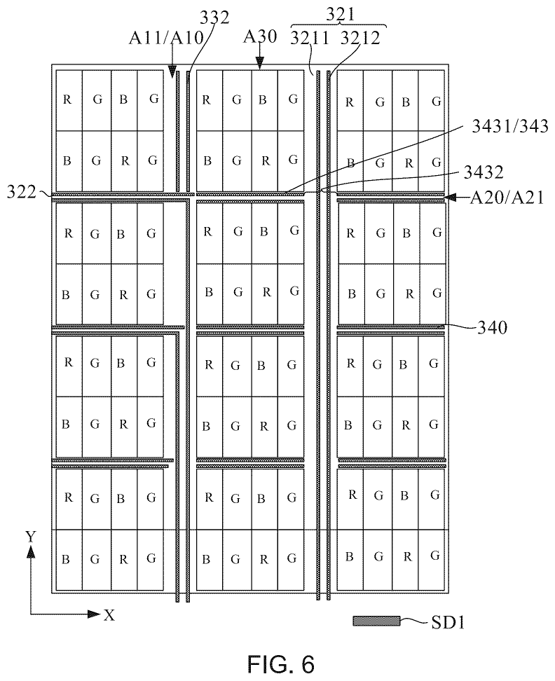

The manner of insulating the third-kind dummy lines 343 from the second sub-leads 3212 will be introduced below. In some embodiments, referring to FIG. 6, at least one third-kind dummy line 343 includes a plurality of first sub-lines 3431 arranged sequentially in the second direction X; a line-passing gap 3432 is formed between two adjacent first sub-lines 3431 in the second direction X; and at least one second sub-lead 3212 passes through the line-passing gap 3432. Since the second sub-lead 3212 passes through the line-passing gap 3432, the second sub-lead 3212 and the first sub-line 3431 do not intersect. As a result, the second sub-lead 3212 is insulated from the first sub-line 3431. That is, the second sub-lead 3212 is insulated from the third-kind dummy line 343.

In some examples, all third-kind dummy lines 343 may each include a plurality of first sub-lines 3431.

In some other embodiments, an insulating layer may be provided at positions where the second sub-leads 3212 and the third-kind dummy lines 343 overlap, so that the second sub-leads 3212 are insulated from the third-kind dummy lines 343.

Some of the above embodiments introduce the wiring rules of the first dummy lines 330 and the second dummy lines 340 when the first leads 321 further include the second sub-leads 3212. The film layers where the first leads 321 and the second leads 322 are located will be introduced below based on the case where the first leads 321 further include the second sub-leads 3212.

In some embodiments, the plurality of first leads 321 include first sub-leads 3211 and second sub-leads 3212. The first sub-leads 3211 are arranged in the second source-drain metal layer SD2. The second sub-leads 3212 and the second leads 322 are arranged in the first source-drain metal layer SD1. A plurality of first leads 321 (including the first sub-leads 3211 and the second sub-leads 3212) are arranged in the first source-drain metal layer SD1 and the second source-drain metal layer SD2. More first leads 321 may be arranged in a single first designated wiring region A11. In a case where all the second leads 322 are arranged in the first source-drain metal layer SD1, all the second dummy lines 340 are arranged in the first source-drain metal layer SD1.

The fan-out leads 320, the first dummy lines 330 and the second dummy lines 340 are introduced in some of the above embodiments. The pixel unit region A30 will be introduced below. Regions between the first wiring regions A10 and the second wiring regions A20 are pixel unit regions A30. In some embodiments, a pixel unit region A30 is provided therein with at least one repeating unit, and a single repeating unit includes a plurality of pixel driving circuits 211.

A plurality of pixel driving circuits 211 in a single repeating unit are used to drive one red sub-pixel R, one blue sub-pixel B and one green sub-pixel G to emit light, respectively. In some other embodiments, referring to FIGS. 4A to 4C, and 6, a plurality of pixel driving circuits 211 in a single repeating unit are used to drive one red sub-pixel R, one blue sub-pixel B, and two green sub-pixels G to emit light, respectively. For example, a single pixel unit region A30 includes two repeating units; a single repeating unit includes four pixel driving circuits 211; and the four pixel driving circuits 211 are used to drive one red sub-pixel R, one blue sub-pixel B, and two green sub-pixels G to emit light, respectively.

In some embodiments, the pixel driving circuit 211 includes a plurality of transistors. In some embodiments, a structure of the pixel driving circuit 211 in the embodiments of the present disclosure varies, which may be set according to actual needs. For example, the structure of the pixel driving circuit may be a structure of “2T1C”, “6T1C”, “7T1C”, “6T2C”, or “7T2C”. Here, “T” represents a thin film transistor, a number before “T” represents the number of thin film transistors, “C” represents a capacitor, and a number before “C” represents the number of capacitors. The pixel driving circuit will be described below by taking a structure of 7T1C as an example.

Referring to FIG. 7A, the pixel driving circuit 211 may include a first reset transistor T1, a compensation transistor T2, a driving transistor T3, a writing transistor T4, a first light-emitting control transistor T5, a second light-emitting control transistor T6, a second reset transistor T7, and a capacitor Cst. Signal lines electrically connected to the pixel driving circuit 211 include a first gate scan signal line G-N, a second gate scan signal line G-P, a reset signal line Rst, a light-emitting control signal line Em, a first initialization signal line Vt1, and a second initialization signal line Vt2.

A gate of the first reset transistor T1 is electrically connected to the reset signal line Rst, a first electrode of the first reset transistor T1 is electrically connected to the first initialization signal line Vt1, and a second electrode of the first reset transistor T1 is electrically connected to a node A. A gate of the compensation transistor T2 is electrically connected to the first gate scan signal line G-N, a first electrode of the compensation transistor T2 is electrically connected to a second electrode of the driving transistor T3, and a second electrode of the compensation transistor T2 is electrically connected to the node A. A gate of the driving transistor T3 is electrically connected to the node A. A gate of the writing transistor T4 is electrically connected to the second gate scan signal line G-P, a first electrode of the writing transistor T4 is electrically connected to the data line Dt, and a second electrode of the writing transistor T4 is electrically connected to a first electrode of the driving transistor T3. A gate electrode of the first light-emitting control transistor T5 and a gate of the second light-emitting control transistor T6 are each electrically connected to the light-emitting control signal line Em. A first electrode of the first light-emitting control transistor T5 is electrically connected to the first power signal line Vdd. A second electrode of the first light-emitting control transistor T5 is electrically connected to the first electrode of the driving transistor T3. A first electrode of the second light-emitting control transistor T6 is electrically connected to the second electrode of the driving transistor T3. A second electrode of the second light-emitting control transistor T6 is electrically connected to the anode of the light-emitting device OLED. A gate of the second reset transistor T7 is electrically connected to the second gate scan signal line G-P, a first electrode of the second reset transistor T7 is electrically connected to the second initialization signal line Vt2, and a second electrode of the second reset transistor T7 is electrically connected to the anode of the light-emitting device OLED. The cathode of the light-emitting device OLED is electrically connected to the second power signal line Vss. A first electrode plate Cst1 of the capacitor Cst is electrically connected to the node A, and a second electrode plate Cst2 of the capacitor Cst is electrically connected to the first power signal line Vdd.

In the circuits provided in the embodiments of the present disclosure, the node A does not represent an actual component, but represent a junction of relevant electrical connections in the circuit diagram. That is, the node is equivalent to the junction point of the related electrical connections in the circuit diagram.

In some embodiments, each transistor in the pixel driving circuit 211 may be a P-type transistor, and the P-type transistor is turned on when the gate receives a low voltage signal. In some other embodiments, each transistor in the pixel driving circuit 211 may be an N-type transistor, and the N-type transistor is turned on when the gate receives a high voltage signal. In addition, in some other embodiments, some of the transistors in the pixel driving circuit 211 are N-type transistors, and the rest of the transistors are P-type transistors. For example, T1 and T2 are N-type transistors, and the rest are P-type transistors. It should be noted that the “high voltage signal” and “low voltage signal” mentioned above are common terms. Generally, the conduction condition of the N-type transistor is that a gate-source voltage difference is greater than a threshold voltage thereof, i.e., a gate voltage of the N-type transistor is greater than a sum of a source voltage thereof and the threshold voltage thereof, the threshold voltage of the N-type transistor is positive, then a gate voltage signal that turns on the N-type transistor is referred to as a high-voltage signal; the conduction condition of the P-type transistor is that an absolute value of a gate-source voltage difference is greater than a threshold voltage thereof, and the threshold voltage of the P-type transistor is negative, i.e., a gate voltage of the P-type transistor is less than a sum of a source voltage thereof and the threshold voltage thereof, then a gate voltage signal that turns on the P-type transistor is referred to as a low voltage signal. The “high” in the “high voltage signal” and “low” in the “low voltage signal” are relative to a reference voltage (e.g., 0 V).

Based on the pixel driving circuit 211 provided in some of the above embodiments, the film layer structure of the array substrate 300 provided in some embodiments of the present disclosure will be introduced.

In some embodiments, referring to FIG. 7B, the array substrate 300 further includes: a first active film layer 350, a first gate metal layer Gate1, a second gate metal layer Gate2, a second active film layer 360, a third gate metal layer Gate3, a first source-drain metal layer SD1, and a second source-drain metal layer SD2 that are sequentially disposed on the first side of the substrate 310. In addition, the array substrate 300 further includes a plurality of insulating layers 380. For example, the insulating layer may be disposed between the first active film layer 350 and the first gate metal layer Gate1, between the first gate metal layer Gate1 and the second gate metal layer Gate2, between the second gate metal layer Gate2 and the second active film layer 360, between the second active film layer 360 and the third gate metal layer Gate3, between the third gate metal layer Gate3 and the first source-drain metal layer SD1, and between the first source-drain metal layer SD1 and the second source-drain metal layer SD2.

Each film layer in the array substrate 300 will be introduced below.

The first active film layer 350 will be firstly introduced. In some embodiments, the first active film layer 350 is disposed between the substrate 310 and the plurality of fan-out leads 320. The second leads 322 of the fan-out leads 320 are closest to the substrate 310. Therefore, the first active film layer 350 is located between the second leads 322 and the substrate 310.

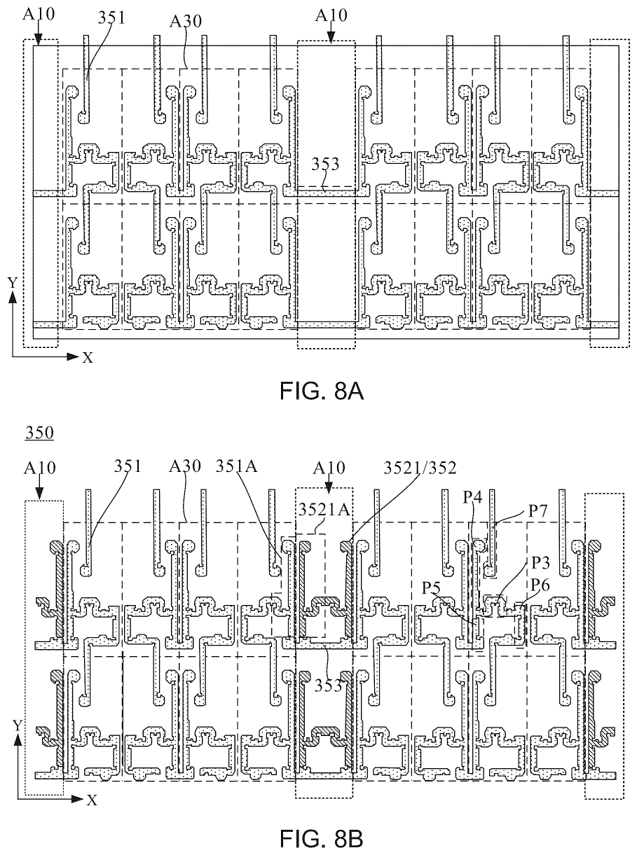

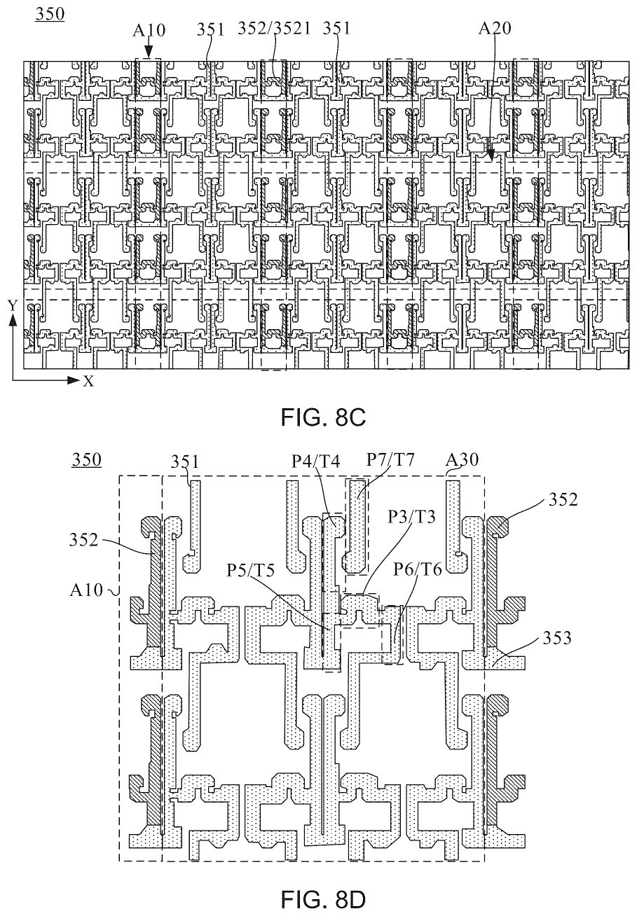

In some embodiments, referring to FIG. 8A, the first active film layer 350 includes pixel active layers 351; the pixel active layer 351 is used to form active layers of at least part of the transistors in the pixel driving circuit 211; and the pixel active layer 351 is disposed in the pixel unit region A30.

The first active film layer 350 may be made of polysilicon.

In an implementation, polysilicon is only provided in the pixel unit region A30, and polysilicon is not provided in the first wiring region A10. That is, only the pixel active layer 351 is arranged on the substrate 310, resulting in a large difference between the density of polysilicon in pixel unit region A30 and the density of polysilicon in the first wiring region A10. The difference in the density of polysilicon will affect the uniformity of polysilicon, which affects the uniformity of the transistors in the pixel driving circuit 211, causing poor uniformity in the display of the display panel 200.

Based on this, in some embodiments, referring to FIGS. 8B and 8C, the first active film layer 350 further includes dummy active layers 352, and the dummy active layer 352 is disposed in the first wiring region A10. The dummy active layer 352 and the pixel active layer 351 are made of the same material, for example, polysilicon. In some embodiments of the present disclosure, since the dummy active layer 352 is arranged in the first wiring region A10, the difference between the density of polysilicon in the first wiring region A10 and the density of polysilicon in the pixel unit region A30 may be reduced. As a result, the uniformity of the density of polysilicon in the first active film layer 350 is improved, which improves the uniformity of transistors, and in turn improves the uniformity of the display of the display panel 200.

In some embodiments, referring to FIGS. 8B and 8C, in a single first wiring region A10, the dummy active layer 352 is symmetrically arranged in the second direction X, so that the structure of the dummy active layer 352 is regular, which facilitates the processing and improves the convenience of fabrication.

In some embodiments, the dummy active layer 352 is disposed in the first wiring region A10. The second wiring region A20 intersects the first wiring region A10. Therefore, the intersection of the second wiring region A20 and the first wiring region A10 belongs to both the second wiring region A20 and the first wiring region A10. No dummy active layer 352 is provided at the intersection of the second wiring region A20 and the first wiring region A10.

In some embodiments, referring to FIGS. 8B and 8C, in a single first wiring region A10, the dummy active layer 352 includes a plurality of dummy active patterns 3521 sequentially arranged in the first direction Y. The dummy active pattern 3521 is disposed between two adjacent pixel unit regions A30 in the second direction X. It can be understood that, in this embodiment, no dummy active pattern 3521 is arranged at the intersection of the second wiring region A20 and the first wiring region A10.

In some examples, referring to FIG. 8B, a single pixel unit region A30 is provided therein with two repeating units. A single repeating unit includes four pixel driving circuits 211. The four pixel driving circuits 211 are used to drive one red sub-pixel R, one blue sub-pixel B, and two green sub-pixels G to emit light, respectively. A single pixel unit A30 includes eight sub-pixel regions. The pixel active layer 351 includes a plurality of pixel active patterns. A single sub-pixel region is provided therein with a single pixel active pattern. A single pixel active pattern is used to form active layers of at least some of transistors in a single pixel driving circuit 211. For example, referring to FIGS. 8B and 8D, a single pixel active pattern includes an active layer P3 of the driving transistor T3 to an active layer P7 of the second reset transistor T7. The driving transistor T3, the writing transistor T4, the first light-emitting control transistor T5, the second light-emitting control transistor T6, and the second reset transistor T7 may be P-type transistors.

An active layer of each transistor includes a first electrode region, a second electrode region, and a channel region connecting the first electrode region and the second electrode region. The first electrode region is electrically connected to the first electrode of the transistor. The second electrode region is electrically connected to the second electrode of the transistor.

In some embodiments, referring to FIG. 8B, the active layer P5 of the first light-emitting control transistor T5 and the active layer P4 of the writing transistor T4 are sequentially arranged in the first direction Y. An end of the active layer P5 of the first light-emitting control transistor T5 away from the active layer P4 of the writing transistor T4 is the first electrode region of the first light-emitting control transistor T5. The first electrode region of the first light-emitting control transistor T5 is electrically connected to the first power signal line Vdd in the second source-drain metal layer SD2.

In some embodiments, referring to FIGS. 8A and 8B, the first active film layer 350 further includes a plurality of first connection patterns 353. Each first wiring region A10 is provided therein with multiple first connection patterns 353 sequentially arranged in the first direction Y. First electrode regions of two first light-emitting control transistors T5 that are respectively located on two sides of the first wiring region A10 are connected through the first connection pattern 353. Since the first electrode region of the first light-emitting control transistor T5 is electrically connected to the first power supply signal line Vdd, the first connection pattern 353 is electrically connected to the first power supply signal line Vdd. By electrically connecting the first power signal line Vdd to the first connection pattern 353, the load of the first power signal line Vdd may be reduced, which improves the uniformity of the display of the display panel 200.

In some embodiments, referring to FIG. 8B, the dummy active pattern 3521 is electrically connected to the first connection pattern 353. Therefore, the dummy active pattern 3521 (i.e., the dummy active layer 352) may be electrically connected to the first power signal line Vdd through the first connection pattern 353. As a result, the dummy active pattern 3521 receives the first power signal from the first power signal line Vdd, which avoids static electricity accumulation in the dummy active pattern 3521.

In some embodiments, referring to FIG. 8B, the dummy active pattern 3521 includes two set patterns 3521A that are sequentially arranged in the second direction X and symmetrically arranged. Therefore, a single dummy active pattern 3521 has an axis of symmetry extending in the first direction Y, and two set patterns 3521A are arranged in axial symmetry with respect to the axis of symmetry.

A single pixel unit region A30 includes a plurality of sub-pixel regions, and a single sub-pixel region is provided therein with a single pixel driving circuit. In a single sub-pixel region, a part of the pixel active layer 351 forms a preset pattern 351A. A set pattern 3521A and a preset pattern 351A in a sub-pixel region adjacent to the set pattern 3521A are sequentially arranged in the second direction X and are symmetrically arranged. Therefore, the structure of the first active film layer 350 is regular, which facilitates processing and improves the convenience of fabrication.

A size of the set pattern 3521A in the first direction Y is equal to a size of the preset pattern 351A in the first direction Y.

In this case, the preset pattern 351A adjacent to the first wiring region A10 overlaps the set pattern 3521A after being moved by a preset distance in the second direction X.

In some embodiments, the pixel driving circuit includes the driving transistor T3, the writing transistor T4, and the first light-emitting control transistor T5.

In a single sub-pixel region, the pixel active layer 351 includes the active layer P3 of the driving transistor T3, the active layer P4 of the writing transistor T4, and the active layer P5 of the first light-emitting control transistor T5. A part of the active layer P3 of the driving transistor T3, the active layer P4 of the writing transistor T4, and the active layer P5 of the first light-emitting control transistor T5 together constitute the preset pattern 351A.

In some examples, the preset pattern 351A includes a part of the active layer P4 of the writing transistor T4.

In some embodiments, a size of a single dummy active pattern 3521 in the first direction Y is greater than or equal to half of a size, in the first direction Y, of the pixel active layer 351 in a single pixel unit region A30, and is less than or equal to the size, in the first direction Y, of the pixel active layer 351 in a single pixel unit region A30. In this way, the density of polysilicon in the first wiring region A10 is closer to the density of polysilicon in the pixel unit region A30, so that the uniformity of the density of polysilicon in the first active film layer 350 is further improved.

The above description introduces the first active film layer 350. Next, the first gate metal layer Gate1 will be introduced in conjunction with the first active film layer 350.

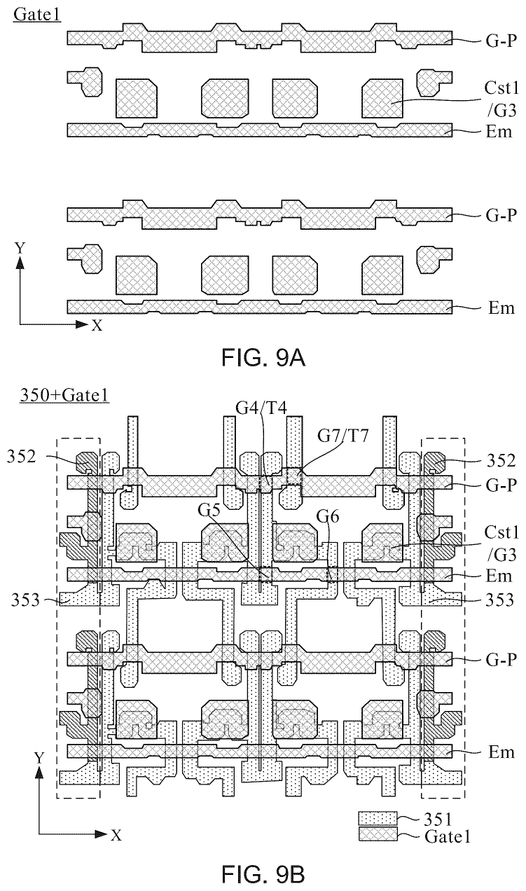

Referring to FIGS. 9A and 9B, the first gate metal layer Gate1 includes a plurality of second gate scan signal lines G-P and a plurality of light-emitting control signal lines Em. The plurality of second gate scan signals G-P extend in the second direction X and are sequentially arranged in the first direction Y. The plurality of light-emitting control signal lines Em extend in the second direction X, and are sequentially arranged in the first direction Y.

In some examples, referring to FIG. 9B, a portion of the second gate scan signal line G-P that overlaps the channel region of the active layer P4 of the writing transistor T4 serves as the gate of the writing transistor T4, and a portion of the second gate scan signal line G-P that overlaps the channel region of the active layer P7 of the second reset transistor T7 serves as the gate G7 of the second reset transistor T7. Therefore, the second gate scan signal line G-P passes through the gate G4 of the writing transistor T4 and the gate G7 of the second reset transistor T7. Thus, the gate G4 of the writing transistor T4 and the gate G7 of the second reset transistor T7 in a single pixel driving circuit 211 are included in the same second gate scan signal line G-P.

In some examples, referring to FIG. 9B, a portion of the light-emitting control signal line Em overlapping the channel region of the active layer P5 of the first light-emitting control transistor T5 serves as the gate G5 of the first light-emitting control transistor T5. A portion of the light-emitting control signal line Em overlapping the channel region of the active layer P6 of the second light-emitting control transistor T6 serves as the gate G6 of the second light-emitting control transistor T6. Therefore, the gate G5 of the first light-emitting control transistor T5 and the gate G6 of the second light-emitting control transistor T6 in a single pixel driving circuit 211 are included in the same light-emitting control signal line Em.

In some examples, referring to FIG. 9A, the first gate metal layer Gate1 further includes the first electrode plates Cst1 of the capacitors Cst. Referring to FIG. 9B, the first electrode plate Cst1 overlaps the active layer P3 of the driving transistor T3. Therefore, a portion of the first electrode plate Cst1 overlapping the channel region of the active layer P3 of the driving transistor T3 may also be used as the gate G3 of the driving transistor T3.

Next, the second gate metal layer Gate2 will be introduced.

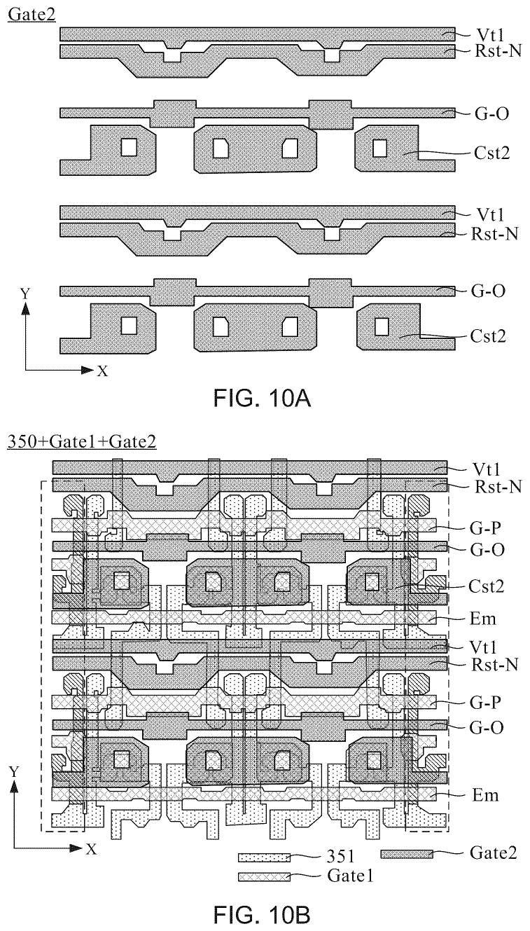

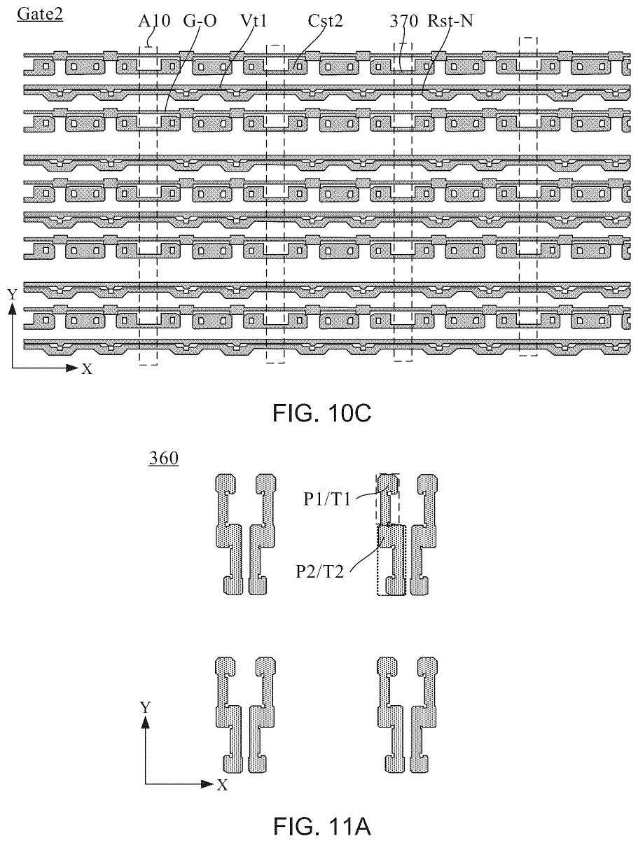

In some embodiments, referring to FIGS. 10A, 10B and 10C, the second gate metal layer Gate2 includes a plurality of first initialization signal lines Vt1. The plurality of first initialization signal lines Vt1 extend in the second direction X and are sequentially arranged in the first direction Y.

The second gate metal layer Gate2 further includes the second electrode plates Cst2 of the capacitors Cst. Referring to FIG. 10B, orthographic projections of the second electrode plate Cst2 and the first electrode plate Cst1 on the substrate 310 overlap.

In some embodiments, referring to FIG. 10C, the second gate metal layer Gate2 further includes second connection patterns 370. Each first wiring region A10 is provided therein with a plurality of second connection patterns 370 sequentially arranged in the first direction Y.

For a row of pixel driving circuits 211, two second electrode plates Cst2 located on both sides of the first wiring region A10 are electrically connected to the second connection pattern 370, so that the two second electrode plates Cst2 located on both sides of the first wiring region A10 are electrically connected. The second electrode plate Cst2 is electrically connected to the first power signal line Vdd. Therefore, the second connection pattern 370 may be electrically connected to the first power signal line Vdd. Since the second electrode plate Cst2 receives the first power signal of a constant voltage, by connecting some of the second electrode plates Cst2 through the second connection patterns 370, the load of the power signal may be reduced, which improves the uniformity of screen brightness.

In some embodiments, referring to FIG. 10C, in a single pixel unit region A30, two second electrode plates Cst2 that are not adjacent to the first wiring region A10 are connected to each other. Since the second electrode plate Cst2 receives the first power signal of a constant voltage, by electrically connecting some of the second electrode plates Cst2, the load of the power signal may be reduced, which improves the uniformity of screen brightness.

Next, the second active film layer 360 will be introduced.

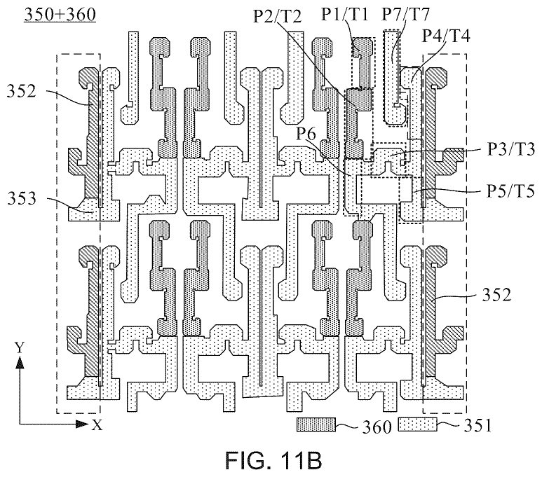

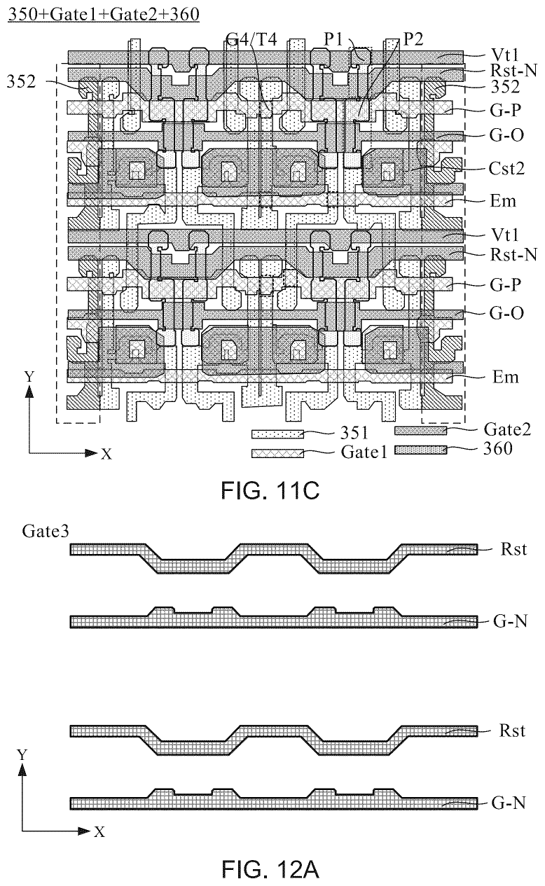

Referring to FIGS. 11A, 11B and 11C, the second active film layer 360 includes the active layer P1 of the first reset transistor T1 and the active layer P2 of the compensation transistor T2. An end of the active layer P1 of the first reset transistor T1 away from the active layer P2 of the compensation transistor T2 is the first electrode region of the first reset transistor T1. The first electrode region of the first reset transistor T1 is electrically connected to the first initialization signal line Vt1 through a via hole.

In some examples, the second active film layer 360 may be made of metal oxide. For example, the metal oxide is Indium Gallium Zinc Oxide (IGZO). In some examples, the first reset transistor T1 and the compensation transistor T2 are N-type transistors.

Referring to FIG. 11B, the active layer P6 of the second light-emitting control transistor T6 and the active layer P2 of the compensation transistor T2 are sequentially arranged in the first direction Y. The active layer P1 of the first reset transistor T1 is located on a side of the active layer P2 of the compensation transistor T2 away from the active layer P6 of the second light-emitting control transistor T6.

Next, the third gate metal layer Gate3 will be introduced.

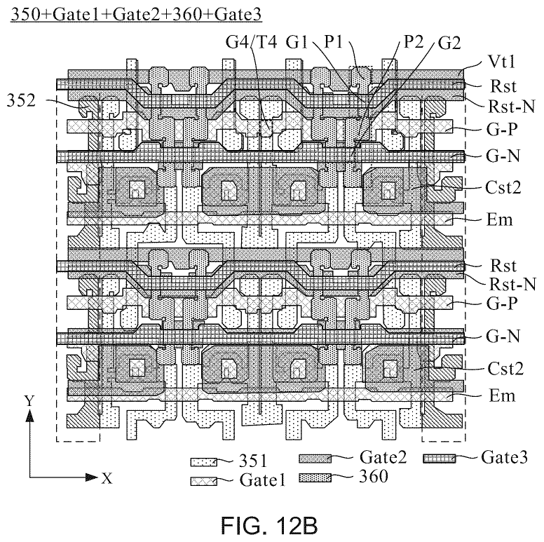

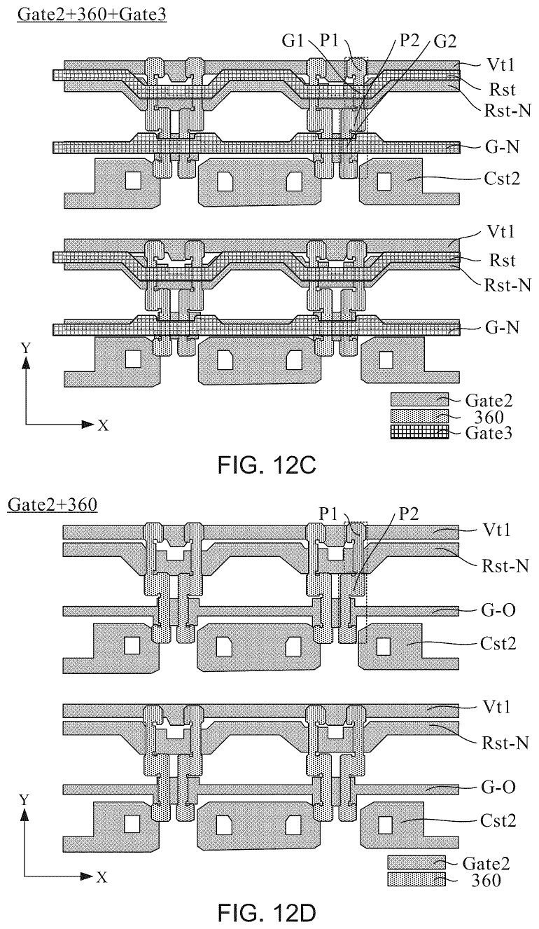

Referring to FIG. 12A, the third gate metal layer Gate3 includes the reset signal lines Rst and the first gate scan signal lines G-N.

Referring to FIGS. 12B and 12C, a portion of the reset signal line Rst overlapping the channel region of the active layer P1 of the first reset transistor T1 is the gate G1 of the first reset transistor T1.

Referring to FIGS. 12B and 12C, a portion of the first gate scan signal line G-N overlapping the channel region of the active layer P2 of the compensation transistor T2 serves as the gate G2 of the compensation transistor T2.

In some of the above embodiments, the gate G1 of the first reset transistor T1 and the gate of the compensation transistor T2 are only located in the third gate metal layer Gate3. In this case, the first reset transistor T1 and the compensation transistor T2 are each a single-gate transistor. In some other embodiments, the first reset transistor T1 and the compensation transistor T2 are each a double-gate transistor. The top gate of the first reset transistor T1 and the top gate of the compensation transistor T2 are located in the third gate metal layer Gate3.

In some examples, the array substrate 300 includes two reset signal lines Rst, one reset signal line Rst is arranged in the third gate metal layer Gate3, and another reset signal line is arranged in the second gate metal layer Gate2. For the convenience of distinction, the reset signal line arranged in the second gate metal layer Gate2 may be marked as Rst-N. The array substrate 300 includes two first gate scan signal lines G-N, one first gate scan signal line G-N is arranged in the third gate metal layer Gate3, and another first gate scan signal line is arranged in the second gate metal layer Gate2. For the convenience of distinction, the first gate scan signal line arranged in the second gate metal layer Gate2 may be marked as G-O.

Referring to FIGS. 12C and 12D, the second gate metal layer Gate2 includes reset signal lines Rst-N and first gate scan signal lines G-O. A portion of the reset signal line Rst-N overlapping the active layer P1 of the first reset transistor T1 serves as the bottom gate of the first reset transistor T1. A portion of the first gate scan signal line G-O overlapping the active layer P2 of the compensation transistor T2 serves as the bottom gate of the compensation transistor T2.

In addition, the second gate metal layer Gate2 further includes first initialization signal lines Vt1. In some embodiments, in a row of sub-pixel regions, the first gate scan signal line G-O, the reset signal line Rst-N and the first initialization signal line Vt1 are sequentially arranged in the first direction Y.

The first source-drain metal layer SD1 will be introduced below.

In some embodiments, no second sub-lead 3212 is arranged in the first source-drain metal layer SD1. The first source-drain metal layer SD1 includes a plurality of second initialization signal lines Vt2. The plurality of second initialization signal lines Vt2 extend in the second direction X and are sequentially arranged in the first direction Y. The second initialization signal line Vt2 is electrically connected to the first electrode region of the second reset transistor T7. In this case, a single second initialization signal line Vt2 may pass through all the first wiring regions A10.

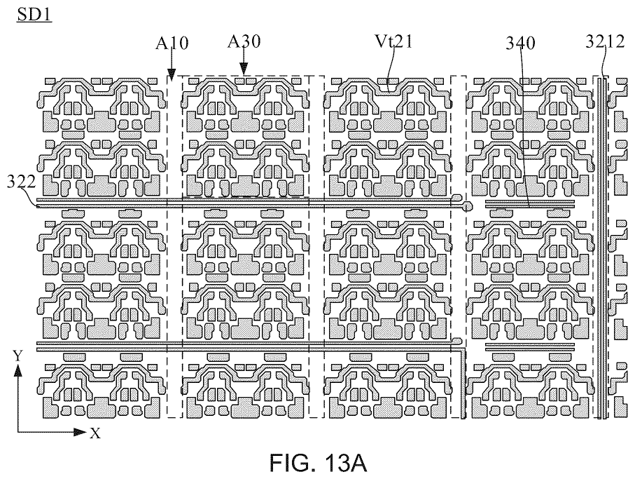

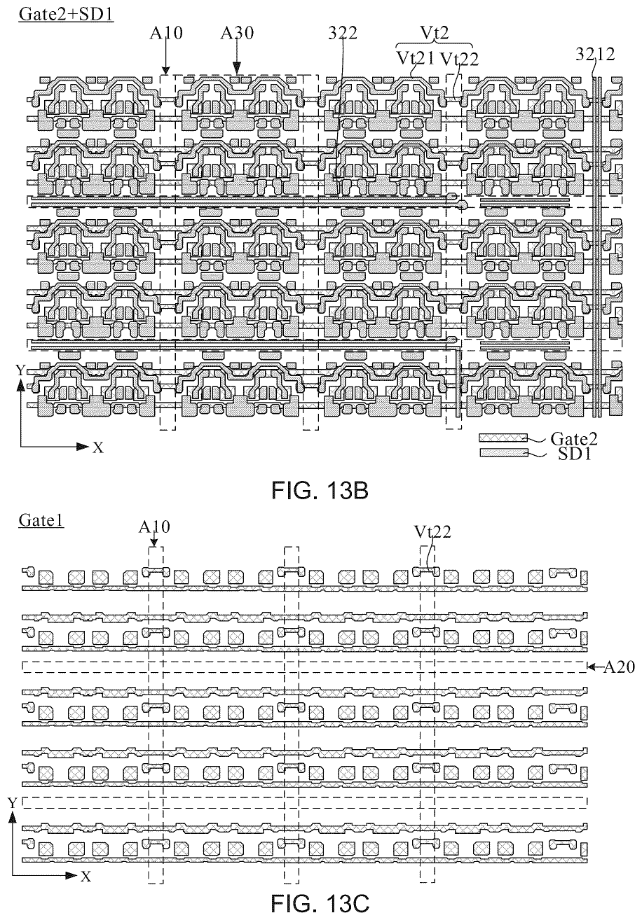

In some other examples, referring to FIG. 13A, the second sub-leads 3212 are further provided in the first source-drain metal layer SD1. Based on this, referring to FIG. 13B, the second initialization signal line Vt2 includes initial signal lines Vt21 and initial jumpers Vt22 that are alternately arranged. Referring to 13A, the initial signal lines Vt21 are arranged in the first source-drain metal layer SD1, and the initial jumpers Vt22 are arranged in the first gate metal layer Gate1. An orthographic projection of a part of an initial signal line Vt21 on the substrate 310 is located within a row of sub-pixel regions in a pixel unit region A30. Referring to FIG. 13C, initial jumpers Vt22 are disposed in the first wiring region A10. The first wiring region A10 is provided therein with a plurality of initial jumpers V22 sequentially arranged in the first direction Y. The initial jumper V22 and the initial signal line Vt21 are electrically connected through a via hole. The initial jumpers Vt22 are arranged in the first gate metal layer Gate1 to bypass the second sub-leads 3212 in the first source-drain metal layer SD1, thereby preventing the second sub-leads 3212 from being short-circuited with the second initialization signal lines Vt2. In addition, in a case where the second dummy lines 332 are also provided in the first source-drain metal layer SD1, the initial jumpers Vt22 may also bypass the second dummy lines 332 to prevent the second dummy lines 332 from being short-circuited with the second initialization signal lines Vt2.

Moreover, it should be noted that the above-mentioned embodiment in which the second initialization signal line Vt2 includes initial signal lines Vt21 and initial jumpers Vt22 that are alternately arranged is also applicable to the case where no second sub-lead 3212 is provided in the first source-drain metal layer SD1.

In some embodiments, referring to FIG. 13A, the first source-drain metal layer SD1 further includes the second leads 322 and the second dummy lines 340.

The second source-drain metal layer SD2 will be introduced below.

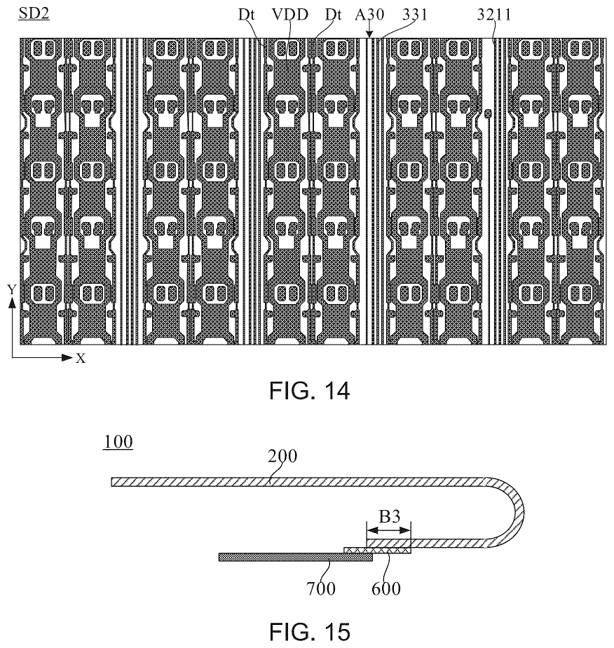

In some embodiments, referring to FIG. 14, the second source-drain metal layer SD2 includes a plurality of first power signal lines Vdd. The plurality of first power signal lines Vdd extend in the first direction Y, and are sequentially arranged in the second direction X.

In some embodiments, referring to FIG. 14, the second source-drain metal layer SD2 includes a plurality of data lines Dt. The plurality of data lines Dt extend in the first direction Y and are sequentially arranged in the second direction X. A data line Dt is electrically connected to first electrode regions of writing transistors T4 in a column of pixel driving circuits 211.

The second source-drain metal layer SD2 is further provided with a plurality of first sub-leads 3211 and a plurality of first-type dummy lines 331. The first sub-leads 3211 and the first-type dummy lines 331 are arranged in the first wiring regions A10.

Some embodiments of the present disclosure provide a display panel 200. Referring to FIG. 1D, the display panel 200 includes: the array substrate 300 provided in some of the above embodiments, a light-emitting device layer 400, and an encapsulation layer 500. The light-emitting device layer 400 is disposed on a side of the array substrate 100 away from the substrate 310, and the encapsulation layer 500 is disposed on a side of the light-emitting device layer 400 away from the array substrate 300. The display panel 200 provided in the embodiments of the present disclosure has all the beneficial effects of the array substrate 300 provided in the above embodiments, which will not be repeated here.

A bottom layer of the array substrate 300 is the substrate 310, and a top layer of the array substrate 300 is the second source-drain metal layer SD2. In some embodiments, referring to FIG. 7B, a planarization layer PLN is provided on a side of the second source-drain metal layer SD2 away from the substrate 310, and the light-emitting device layer 400 is disposed on the planarization layer PLN.

The display panel 200 provided in the embodiments of the present disclosure may be, for example, an organic light-emitting diode (OLED) display panel, an active matrix organic light-emitting diode (AMOLED) display panel, etc.

The display apparatus 100 provided in some embodiments of the disclosure provide includes the display panel 200 provided in any one of the above embodiments. Therefore, beneficial effects of the display apparatus 100 provided in the embodiments of the present disclosure are the same as the beneficial effects of the display panel 200 provided in any of the above embodiments, which will not be repeated here.

Referring to FIG. 1H, the display panel 200 includes a bonding region B3, and the bonding region B3 is located on a side of the lead-out region B10 away from the display region AA. The display panel 200 includes the array substrate 300. The array substrate 300 includes the substrate 310. The substrate 310 includes the display region AA, the peripheral region BB, the lead-out region B10, and the bonding region B3. Therefore, the display region AA of the display panel 200 and the display region AA of the substrate 310 are the same region; the peripheral region BB of the display panel 200 and the peripheral region BB of the substrate 310 are the same region; the lead-out region B10 of the display panel 200 and the lead-out region B10 of the substrate 310 are the same region; and the bonding region B3 of the display panel 200 and the bonding region B3 of the substrate 310 are the same region.

In some embodiments, referring to FIG. 15, the display apparatus 100 further includes an FPC 600 and a main control circuit board 700. The bonding region B3 is provided therein with a plurality of pins. An end of the FPC 600 is bonded to the bonding region B3, and another end of the FPC 600 is electrically connected to the main control circuit board 700.

Referring to FIG. 1H, in some examples, the lead-out region B10 includes a bending region B2, a second fan-out region B4 and a test circuit region B5; the display panel 200 further includes a chip region B6; the lead-out region B10 is located between the chip region B6 and the display region AA; and the bonding region B3 is located on a side of the chip region B6 away from the lead-out region B10. In this case, the first leads 321 may extend to the chip region B6 through the bending region B2, the second fan-out region B4 and the test circuit region B5. The chip region B6 is provided therein with a plurality of pins. The plurality of pins are electrically connected to the plurality of first leads 321, respectively. The driver IC may be bonded to the plurality of pins in the chip region B6 and then be electrically connected to the plurality of first leads 321.

The bonding region B3 is provided therein with a plurality of pins. The first power signal lines Vdd may extend to the bonding region B3 through the lead-out region B10 and the chip region B6, and are electrically connected to at least some of the plurality of pins in the bonding region B3. Lead-out portions of the first power signal lines Vdd may be gathered in the second fan-out region B4 in the lead-out region B10. An end of the FPC 600 may be bonded to and electrically connected to at least some of the pins in the bonding region B3, and another end of the FPC 600 may be bonded to and electrically connected to the main control circuit board 700. Therefore, through the FPC 600, the main control circuit board 700 may transmit the first power signals to the lead-out portions of the first power signal lines Vdd via some of the pins and then to the first power signal lines Vdd.

Referring to FIG. 1H, in some other examples, the lead-out region B10 does not include the bending region, and a side of the lead-out region away from the display region is provided with no chip region. In this case, the lead-out region B10 includes the second fan-out region B4 and the test circuit region B5, and the bonding region B3 is disposed on the side of the lead-out region B10 away from the display region AA. In this case, the first leads 321 may extend to the bonding region B3 through the lead-out region B10, and are electrically connected to the plurality of pins in the bonding region B3. The driver IC is bonded to the FPC, and the FPC is bonded to the plurality of pins in the bonding region B3. In this example, the FPC is bent to the back of the display panel 200.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. An array substrate, comprising:
a substrate having a display region and a lead-out region located on a side of the display region, wherein the display region includes first wiring regions and second wiring regions that are arranged crosswise, the first wiring regions extend in a first direction, and the second wiring regions extend in a second direction intersecting the first direction, the first direction pointing from the lead-out region to the display region;
a plurality of data lines located on a first side of the substrate and disposed in the display region, the plurality of data lines all extending in the first direction and being sequentially arranged in the second direction;
a plurality of fan-out leads located on the first side of the substrate, wherein a fan-out lead includes a first lead and a second lead; the first lead extends in the first direction and extends from the lead-out region to a first wiring region; the second lead extends in the second direction and is located in a second wiring region; an end of the second lead is electrically connected to the first lead, and another end of the second lead is electrically connected to one of the plurality of data lines; and the second lead and the data line are arranged in different layers;
a plurality of first dummy lines located on the first side of the substrate and extending in the first direction, wherein the plurality of first dummy lines are disposed in the first wiring regions, and are located on a side, away from the lead-out region, of all first leads as a whole; and
a plurality of second dummy lines located on the first side of the substrate and extending in the second direction, wherein the plurality of second dummy lines are disposed in the second wiring regions; a part of the second dummy lines is located in a second wiring region where no second lead is arranged; and another part of the second dummy lines is located in the second wiring region where the second lead is arranged and is located on at least one side of the second lead in the second direction.

2. The array substrate according to claim 1, wherein
regions between the first wiring regions and the second wiring regions are pixel unit regions, a pixel unit region of the pixel unit regions is provided therein with at least one repeating unit, and a repeating unit includes a plurality of pixel driving circuits;
a pixel driving circuit includes a plurality of transistors;
the array substrate further comprises a first active film layer located on the first side of the substrate; the first active film layer includes dummy active layers and pixel active layers; a pixel active layer is used to form active layers of at least some of the transistors in the pixel driving circuit, and the pixel active layer is disposed in the pixel unit region; and a dummy active layer is disposed in the first wiring region.

3. The array substrate according to claim 2, further comprising:
a plurality of first power signal lines located on the first side of the substrate and disposed in the display region, wherein the plurality of first power signal lines all extend in the first direction and are sequentially arranged in the second direction; and the dummy active layer is electrically connected to a first power signal line; and/or
wherein in the first wiring region, the dummy active layer is symmetrically arranged in the second direction.

4. (canceled)

5. The array substrate according to claim 2, wherein
in the first wiring region, the dummy active layer includes a plurality of dummy active patterns sequentially arranged in the first direction, and a dummy active pattern is disposed between two adjacent pixel unit regions in the second direction;
the dummy active pattern includes two set patterns sequentially arranged in the second direction and symmetrically arranged;
the pixel unit region includes a plurality of sub-pixel regions, and a sub-pixel region is provided therein with a pixel driving circuit; in the sub-pixel region, a part of the pixel active layer constitutes a preset pattern;
wherein a set pattern and a preset pattern in a sub-pixel region adjacent to the set pattern are sequentially arranged in the second direction and are symmetrically arranged.

6. The array substrate according to claim 5, wherein
the pixel driving circuit includes a driving transistor, a writing transistor, and a first light-emitting control transistor;
in the sub-pixel region, the pixel active layer includes an active layer of the driving transistor, an active layer of the writing transistor, and an active layer of the first light-emitting control transistor; wherein a part of the active layer of the driving transistor, the active layer of the writing transistor, and the active layer of the first light-emitting control transistor together constitute a preset pattern; and/or
a size of the dummy active pattern in the first direction is greater that or equal to half of a size, in the first direction, of the pixel active layer in the pixel unit region, and is less than or equal to the size, in the first direction, of the pixel active layer in the pixel unit region.

7-9. (canceled)

10. The array substrate according to claim 1, wherein
the plurality of first dummy lines are arranged in the same layer as at least part of the first leads, and at least part of the plurality of second dummy lines are arranged in the same layer as at least part of second leads.

11. The array substrate according to claim 10, further comprising:
a plurality of first power signal lines located on the first side of the substrate and disposed in the display region, wherein the plurality of first power signal lines all extend in the first direction and are sequentially arranged in the second direction; the first dummy lines and the second dummy lines are electrically connected to the first power signal lines.

12. The array substrate according to claim 11, wherein
a direction pointing from a center line of the display region in the second direction to any side of the display region in the second direction is a set direction;
lengths of portions of a plurality of first leads extending to the display region decrease sequentially in the set direction;
a second lead, to which a first lead closer to the center line is electrically connected, is further away from the lead-out region.

13. The array substrate according to claim 12, wherein
a minimum closed pattern region where all first leads located on a same side of the center line are located is a first routing region; a minimum closed pattern region where all second leads located on a same side of the center line are located is a second routing region; a part of the display region except for first routing regions and second routing regions is a third routing region;
the plurality of first dummy lines are disposed in the second routing regions and the third routing region, and a part of a first dummy line located in the second routing region is insulated from any second lead;
the plurality of second dummy lines are disposed in the first routing regions and the third routing region, and a part of a second dummy line located in the first routing region is insulated from any first lead.

14. The array substrate according to claim 13, wherein
at least one first lead is a first sub-lead, and the first sub-lead is disposed on a side of the second leads away from the substrate;
at least one first dummy line is a first-type dummy line, the first-type dummy line is arranged in the same layer as the first sub-lead, and the first-type dummy line is disposed in the second routing region and the third routing region.

15. The array substrate according to claim 14, wherein
a first wiring region overlapping the first routing region is a first designated wiring region, and the first designated wiring region is provided therein with a plurality of first-type dummy lines;
in the first designated wiring region, a first-type dummy line closer to the center line has a smaller length in the first direction; and
wherein a number of first-type dummy lines in the first designated wiring region is the same as a number of first sub-leads in the first designated wiring region; in the first designated wiring region, the plurality of first-type dummy lines sequentially arranged in the set direction are in one-to-one correspondence with a plurality of first sub-leads sequentially arranged in the set direction; a distance between an end of a first-type dummy line close to the lead-out region and an end of a first sub-lead corresponding to the first-type dummy line away from the lead-out region is L1, where 0 μm<L1≤3 μm.

16. (canceled)

17. The array substrate according to claim 14, wherein
a first wiring region overlapping the first routing region is a first designated wiring region, and the first designated wiring region is provided therein with a plurality of first-type dummy lines;
in the first designated wiring region, lengths of the plurality of the first-type dummy lines in the first direction are equal; and
wherein in the first designated wiring region, a first sub-lead with a maximum length in the first direction is a first designated lead; a distance between an end of a first-type dummy line close to the lead-out region and an end of the first designated lead away from the lead-out region is L2, where 0 μm<L2≤3 μm.

18. (canceled)

19. The array substrate according to claim 14, wherein
a first wiring region that does not overlap the first routing region is a first set wiring region; in the first set wiring region, lengths of a plurality of first-type dummy lines are equal; and/or
second dummy lines located in the second wiring region where no second lead is arranged are first-kind dummy lines; a first-kind dummy line is electrically connected to a first power signal line through a via hole; and a first-type dummy line is electrically connected to the first-kind dummy line through a via hole.

20. (canceled)

21. (canceled)

22. The array substrate according to claim 14, wherein
a second wiring region overlapping the second routing region is a second designated wiring region;
a second dummy line located on a side of the second lead away from the center line is a second-kind dummy line;
in a part of the second designated wiring region on a side of the center line, a plurality of second-kind dummy lines are provided, and a number of second-kind dummy lines is equal to a number of second leads;
a plurality of second-kind dummy lines sequentially arranged in the first direction are in one-to-one correspondence with a plurality of second leads sequentially arranged in the first direction; a distance between an end of a second-kind dummy line close to the center line and an end of a second lead corresponding to the second-kind dummy line away from the center line is L3, where 0 μm<L3≤3 μm.

23. The array substrate according to claim 14, wherein
a second wiring region overlapping the second routing region is a second designated wiring region;
a second dummy line located on a side of the second lead away from the center line is a second-kind dummy line;
in a part of the second designated wiring region on a side of the center line, a plurality of second-kind dummy lines are provided, and lengths of the plurality of second-kind dummy lines in the second direction are equal; and
wherein in the part of the second designated wiring region on the side of the center line, a second lead with a maximum length in the second direction is a second designated lead; and a distance between an end of a second-kind dummy line close to the center line and an end of the second designated lead away from the center line is L4, where 0 μm<L4≤3 μm.

24. (canceled)

25. (canceled)

26. The array substrate according to claim 14, further comprising:
at least one gate metal layer located on the first side of the substrate;
a first source-drain metal layer located on a side of the at least one gate metal layer away from the substrate; and
a second source-drain metal layer located on a side of the first source-drain metal layer away from the substrate;
wherein the data lines are arranged in the second source-drain metal layer, the first power signal lines are arranged in the second source-drain metal layer, the first sub-lead is arranged in the second source-drain metal layer, and the second leads are arranged in the first source-drain metal layer and/or the at least one gate metal layer.

27. The array substrate according to claim 14, wherein
at least one first lead is a second sub-lead, and the second sub-lead and the second leads are arranged in the same layer;
another part of the plurality of first dummy lines are second-type dummy lines; the second-type dummy lines and the second sub-lead is arranged in the same layer; and the second-type dummy lines are disposed in the third routing region;
wherein second dummy lines located in the first routing region are third-kind dummy lines, a third-kind dummy line is electrically connected to a first power signal line through a via hole, and any third-kind dummy line is insulated from the second sub-lead; and
wherein at least one of the third-kind dummy lines includes a plurality of first sub-lines sequentially arranged in the second direction; a line-passing gap is formed between two adjacent first sub-lines in the second direction; and at least one second sub-lead passes through the line-passing gap.

28. (canceled)

29. (canceled)

30. The array substrate according to claim 27, further comprising:
at least one gate metal layer located on the first side of the substrate;
a first source-drain metal layer located on a side of the at least one gate metal layer away from the substrate; and
a second source-drain metal layer located on a side of the first source-drain metal layer away from the substrate;
wherein the data lines are arranged in the second source-drain metal layer, the first power signal lines are arranged in the second source-drain metal layer, the first sub-lead is arranged in the second source-drain metal layer, and the second sub-lead and the second leads are arranged in the first source-drain metal layer.

31. A display panel, comprising:
the array substrate according to claim 1;
a light-emitting device layer located on a side of the array substrate away from the substrate;
an encapsulation layer located on a side of the light-emitting device layer away from the array substrate.

32. A display apparatus, comprising:
the display panel according to claim 31, the display panel including a bonding region, and the bonding region being located on a side of the lead-out region away from the display region;
a flexible printed circuit, an end of the flexible printed circuit being bonded to the bonding region; and
a main control circuit board electrically connected to another end of the flexible printed circuit.
